(19) United States
(12) Patent Application Publication
(10) Pub. No.: US 2014/0051218 A1
(43) Pub. Date: Feb. 20, 2014

(54) THIN FILM SEMICONDUCTOR DEVICE COMPRISING A POLYCRYSTALLINE SEMICONDUCTOR LAYER FORMED ON AN INSULATION LAYER HAVING DIFFERENT THICKNESS

(71) Applicant: Samsung Display Co., Ltd., Yongin-city (KR)

(72) Inventors: Won-Kyu LEE, Yongin-city (KR); Tae-Hoon YANG, Yongin-city (KR); Bo-Kyng CHOI, Yongin-city (KR); Byoung-Kwon CHOO, Yongin-city (KR); Sang-Ho MOON, Yongin-city (KR); Kyu-Sik CHO, Yongin-city (KR); Yong-Hwan PARK, Yongin-city (KR); Joon-Hoo CHOI, Yongin-city (KR); Min-Chul SHIN, Yongin-city (KR); Yun-Gyu LEE, Yongin-city (KR)

(73) Assignee: Samsung Display Co., Ltd., Yongin-city (KR)

(21) Appl. No.: 14/067,454

(22) Filed: Oct. 30, 2013

Related U.S. Application Data
(62) Division of application No. 12/909,324, filed on Oct. 21, 2010.

(30) Foreign Application Priority Data
Jan. 14, 2010 (KR) 10-2010-0003515

(51) Int. Cl. H01L 29/66; H01L 21/02; H01L 21/8234

(52) U.S. Cl. CPC H01L 29/66742; H01L 21/8234; H01L 21/02595
USPC 438/158

(57) ABSTRACT

In an organic light emitting diode (OLED) display and a manufacturing method thereof, the OLED display includes a substrate main body; an insulation layer pattern formed on the substrate main body, and including a first thickness layer and a second thickness layer thinner than the first thickness layer; a metal catalyst that is scattered on the first thickness layer of the insulation layer pattern; and a polycrystalline semiconductor layer formed on the insulation layer pattern, and divided into a first crystal area corresponding to the first thickness layer and to a portion of the second thickness layer adjacent to the first thickness layer and a second crystal area corresponding to the remaining part of the second thickness layer. The first crystal area of the polycrystalline semiconductor layer is crystallized through the metal catalyst, and the second crystal area of the polycrystalline semiconductor layer is solid phase crystallized.

### CROSS REFERENCE TO RELATED APPLICATION

This application is a divisional of U.S. patent application Ser. No. 12/909,324, filed on Oct. 21, 2010, and claims priority to and the benefit of Korean Patent Application No. 10-2010-0003515, filed on Jan. 14, 2010, both of which are incorporated by reference for all purposes as if set forth herein.

### BACKGROUND

1. Field

The described technology relates generally to an organic light emitting diode (OLED) display and a manufacturing method thereof. More particularly, the described technology relates generally to an organic light emitting diode (OLED) display having a polycrystalline semiconductor layer on which a plurality of thin-film transistors formed in a pixel area are crystallized by different methods according to usage, and a manufacturing method thereof.

2. Description of the Related Art

An organic light emitting diode display (OLED) displays images by using organic light emitting elements for emitting light. Light is generated by energy that occurs when excitons generated by a combination of electrons and holes in the organic emission layer fall from an excited state to a ground state, and the organic light emitting diode (OLED) displays an image by using the light.

A plurality of thin film transistors used by the organic light emitting diode (OLED) display require different characteristics with correlation of benefit in return according to usage. In detail, some thin film transistors require high current driving characteristics, and some thin film transistors require low leakage current characteristics.

The characteristics of the thin film transistors are determined according to the crystallization method of the semiconductor layer. However, it is not easy to crystallize the semiconductor layer of a thin film transistor so as to simultaneously satisfy all the characteristics required for the organic light emitting diode (OLED) display.

Also, it is further difficult to crystallize semiconductor layers of a plurality of thin film transistors formed in a single pixel area with different methods according to usage. Here, the pixel represents the minimum unit for displaying an image.

The above information disclosed in this Background section is only for enhancement of understanding of the background of the described technology and therefore it may contain information that does not form the prior art that is already known in this country to a person of ordinary skill in the art.

### SUMMARY

According to an aspect of the present invention, there is provided an organic light emitting diode (OLED) display having a polycrystalline semiconductor layer on which a plurality of thin film transistors formed in a single pixel area are crystallized with different methods according to their usage.

According to another aspect of the present invention, there is provided a method for efficiently manufacturing the organic light emitting diode (OLED) display.

An exemplary embodiment provides an organic light emitting diode (OLED) display including: a substrate main body; an insulation layer pattern formed on the substrate main body, and including a first thickness layer and a second thickness layer thinner than the first thickness layer; a metal catalyst that is scattered on the first thickness layer of the insulation layer pattern; and a polycrystalline semiconductor layer formed on the insulation layer pattern, and divided into a first crystal area corresponding to the first thickness layer and a portion of the second thickness layer adjacent to the first thickness layer and a second crystal area corresponding to the remaining second thickness layer.

The first crystal area of the polycrystalline semiconductor layer is crystallized through the metal catalyst, and the second crystal area of the polycrystalline semiconductor layer is formed through solid phase crystallization (SPC).

The metal catalyst includes at least one of nickel (Ni), palladium (Pd), titanium (Ti), silver (Ag), gold (Au), tin (Sn), antimony (Sb), copper (Cu), cobalt (Co), molybdenum (Mo), terbium (Tb), ruthenium (Ru), cadmium (Cd), and platinum (Pt).

The metal catalyst with a dose amount within the range of 1.0e10 atoms/cm² to 1.0e14 atoms/cm² is scattered on the first thickness layer of the insulation layer pattern.

The insulation layer pattern includes at least one of tetra ethyl ortho silicate (TEOS), silicon nitride, silicon dioxide, and silicon oxynitride.

The organic light emitting diode display further includes a gate electrode formed between the substrate main body and the insulation layer pattern to be partially overlapped on the polycrystalline semiconductor layer, and a source electrode and a drain electrode formed on the polycrystalline semiconductor layer to be respectively connected to the polycrystalline semiconductor layer.

The gate electrode, the polycrystalline semiconductor layer, the source electrode, and the drain electrode form a thin film transistor.

The thin film transistor includes a first thin film transistor using at least a part of the first crystal area of the polycrystalline semiconductor layer, and a second thin film transistor using the second crystal area of the polycrystalline semiconductor layer.

The gate electrode is overlapped on the second crystal area of the polycrystalline semiconductor layer.

The substrate main body includes a plurality of pixel areas, and at least one first thin film transistor and at least one second thin film transistor are respectively formed in the single pixel area.

The organic light emitting diode display further includes a gate electrode separately disposed from the polycrystalline semiconductor layer so as to be partially overlapped on the polycrystalline semiconductor layer, and a source electrode and a drain electrode separately disposed from the gate electrode and respectively connected to the polycrystalline semiconductor layer

The gate electrode, the polycrystalline semiconductor layer, the source electrode, and the drain electrode form a thin film transistor.

The thin film transistor includes a first thin film transistor using at least a part of the first crystal area of the polycrystalline semiconductor layer, and a second thin film transistor using the second crystal area of the polycrystalline semiconductor layer.

The gate electrode is overlapped on the second crystal area of the polycrystalline semiconductor layer.

The substrate main body includes a plurality of pixel areas, and at least one first thin film transistor and at least one second thin film transistor are respectively formed in the single pixel area.

The insulation layer pattern further includes a gradient thickness layer having a sloped cross-section from the first thickness layer to the second thickness layer.

When the gradient thickness layer becomes thinner, concentration of the metal catalyst that is scattered on the gradient thickness layer is reduced.

When the gradient of the gradient thickness layer becomes gentle, the first crystal area of the polycrystalline semiconductor layer is relatively reduced, and when the gradient of the gradient thickness layer becomes sharp, the first crystal area of the polycrystalline semiconductor layer is relatively expanded.

Another embodiment provides a method for manufacturing an organic light emitting diode (OLED) display including: providing a substrate main body; forming an insulation layer on the substrate main body; scattering a metal catalyst on the insulation layer; forming an insulation layer pattern including a first thickness layer and a second thickness layer that is thinner than the first thickness layer by patterning the insulation layer on which the metal catalyst is scattered, through a photolithography process; forming an amorphous silicon layer on the insulation layer pattern; and forming a polycrystalline semiconductor layer that is divided into a first crystal area that is crystallized through the metal catalyst by crystallizing the amorphous silicon layer and a second crystal area that is formed through solid phase crystallization (SPC).

The metal catalyst includes at least one of nickel (Ni), palladium (Pd), titanium (Ti), silver (Ag), gold (Au), tin (Sn), antimony (Sb), copper (Cu), cobalt (Co), molybdenum (Mo), terbium (Tb), ruthenium (Ru), cadmium (Cd), and platinum (Pt).

A surface layer on which the metal catalyst is scattered is removed from the second thickness layer of the insulation layer pattern.

The first crystal area of the polycrystalline semiconductor layer corresponds to the first thickness layer of the insulation layer pattern and the second thickness layer that is near the first thickness layer, and the second crystal area of the polycrystalline semiconductor layer corresponds to the remaining second thickness layer of the insulation layer pattern.

The metal catalyst with a dose amount within the range of 1.0e10 atoms/cm² to 1.0e14 atoms/cm² is scattered on the first thickness layer of the insulation layer pattern.

The insulation layer pattern includes at least one of tetra ethyl ortho silicate (TEOS), silicon nitride, silicon dioxide, and silicon oxynitride.

The method further includes forming a gate electrode between the substrate main body and the insulation layer pattern to be partially overlapped on the polycrystalline semiconductor layer, and forming a source electrode and a drain electrode on the polycrystalline semiconductor layer to be respectively connected to the polycrystalline semiconductor layer.

The gate electrode, the polycrystalline semiconductor layer, the source electrode, and the drain electrode form a thin film transistor.

The thin film transistor includes a first thin film transistor using at least a part of the first crystal area of the polycrystalline semiconductor layer, and a second thin film transistor using the second crystal area of the polycrystalline semiconductor layer.

The gate electrode is overlapped on the second crystal area of the polycrystalline semiconductor layer.

The substrate main body includes a plurality of pixel areas, and at least one first thin film transistor and at least one second thin film transistor are respectively formed in the single pixel area.

The method further includes forming a gate electrode separately disposed from the polycrystalline semiconductor layer so as to be partially overlapped on the polycrystalline semiconductor layer, and forming a source electrode and a drain electrode separately disposed from the gate electrode and respectively connected to the polycrystalline semiconductor layer.

The gate electrode, the polycrystalline semiconductor layer, the source electrode, and the drain electrode form a thin film transistor.

The thin film transistor includes a first thin film transistor using at least a part of the first crystal area of the polycrystalline semiconductor layer, and a second thin film transistor using the second crystal area of the polycrystalline semiconductor layer.

The gate electrode is overlapped on the second crystal area of the polycrystalline semiconductor layer.

The substrate main body includes a plurality of pixel areas, and at least one first thin film transistor and at least one second thin film transistor are respectively formed in the single pixel area.

The insulation layer pattern further includes a gradient thickness layer having a sloped cross-section from the first thickness layer to the second thickness layer.

The gradient thickness layer of the insulation layer pattern is formed through a gradient-structured photoresist pattern generated by using a mask for gradually controlling exposure.

When the gradient thickness layer becomes thinner, concentration of the metal catalyst that is scattered on the gradient thickness layer is reduced.

When the gradient of the gradient thickness layer becomes gentle, the first crystal area of the polycrystalline semiconductor layer is relatively reduced, and when the gradient of the gradient thickness layer becomes sharp, the first crystal area of the polycrystalline semiconductor layer is relatively expanded.

According to the exemplary embodiments, the organic light emitting diode (OLED) display can have a plurality of thin film transistors including a polycrystalline semiconductor layer crystallized at each pixel area with different methods according to usage.

Also, the organic light emitting diode (OLED) display can be efficiently manufactured.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 shows a top plan view of a configuration of an organic light emitting diode (OLED) display according to an embodiment of the present invention;

FIG. 2 shows a circuit diagram of a pixel circuit included in an organic light emitting diode (OLED) display shown in FIG. 1;

FIG. 3 shows a magnified cross-sectional view of thin film transistors used for an organic light emitting diode (OLED) display shown in FIG. 1;

FIG. 4 to FIG. 9 show cross-sectional views for sequentially showing a manufacturing process of thin film transistors shown in FIG. 3;

FIG. 10 shows a top plan view of a direction in which crystal grows according to the embodiment shown in FIG. 3;

FIG. 11 shows a magnified partial cross-sectional view of thin film transistors used for an organic light emitting diode (OLED) display according to another embodiment of the present invention;

FIG. 12 to FIG. 15 show cross-sectional views for sequentially indicating a manufacturing process of thin film transistors shown in FIG. 11;

FIG. 16 shows a top plan view of a direction in which crystal grows according to the embodiment shown in FIG. 11;

FIG. 17 shows a magnified partial cross-sectional view of thin film transistors used for an organic light emitting diode (OLED) display according to another embodiment of the present invention;

FIG. 18 to FIG. 22 show cross-sectional views for sequentially indicating a manufacturing process of thin film transistors shown in FIG. 17;

FIG. 23 shows a magnified partial cross-sectional view of thin film transistors used for an organic light emitting diode (OLED) display according to another embodiment of the present invention; and

FIG. 24 to FIG. 27 show cross-sectional views for sequentially indicating a manufacturing process of thin film transistors shown in FIG. 23.

### DETAILED DESCRIPTION

Reference will now be made in detail to the present embodiments of the present invention, examples of which are illustrated in the accompanying drawings, wherein like reference numerals refer to the like elements throughout. The embodiments are described below in order to explain the present invention by referring to the figures.

Accordingly, the drawings and description are to be regarded as illustrative in nature and not restrictive. Like reference numerals designate like elements throughout the specification. In the exemplary embodiments except the first exemplary embodiment, configurations that are different from the first exemplary embodiment will be described.

The size and thickness in the respective configurations shown in the drawings have random values for better understanding and ease of description, and they are not restricted in the exemplary embodiments.

In the drawings, the thickness of layers, films, panels, regions, etc., are exaggerated for clarity. In the drawings, for better understanding and ease of description, thicknesses of layers and areas are exaggerated. It will be understood that when an element such as a layer, film, region, or substrate is referred to as being “formed on” or “disposed on” another element, the layer, film, region, or substrate can be directly on the other element or intervening elements may also be present. Further, as used herein, the term “formed on” is used with the same meaning as “located on” or “disposed on” and is not meant to be limiting regarding any particular fabrication process.

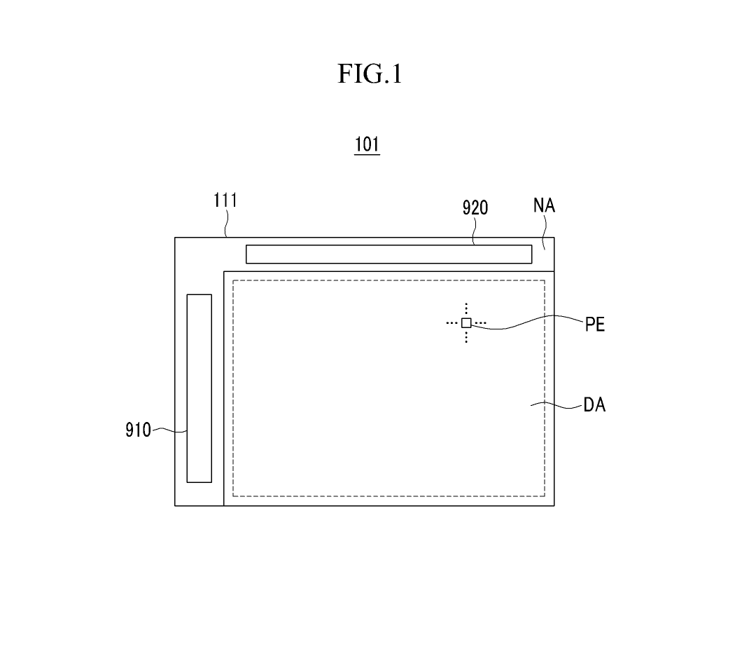

With reference to FIG. 1 to FIG. 3, an organic light emitting diode (OLED) display 101 according to an embodiment will now be described.

As shown in FIG. 1, the organic light emitting diode (OLED) display 101 includes a substrate main body 111 divided into a display area (DA) and a non-display area (NA). A plurality of pixel areas (PE) are formed in the display area (DA) of the substrate main body 111 to display images, and at least one of driving circuits 910 and 920 is formed in the non-display area (NA). Here, the pixel area (PE) represents an area in which a pixel, which a minimum unit for displaying an image, is formed. However, the driving circuits 910 and 920 may not be formed in the non-display area (NA), or part or all of them can be omitted.

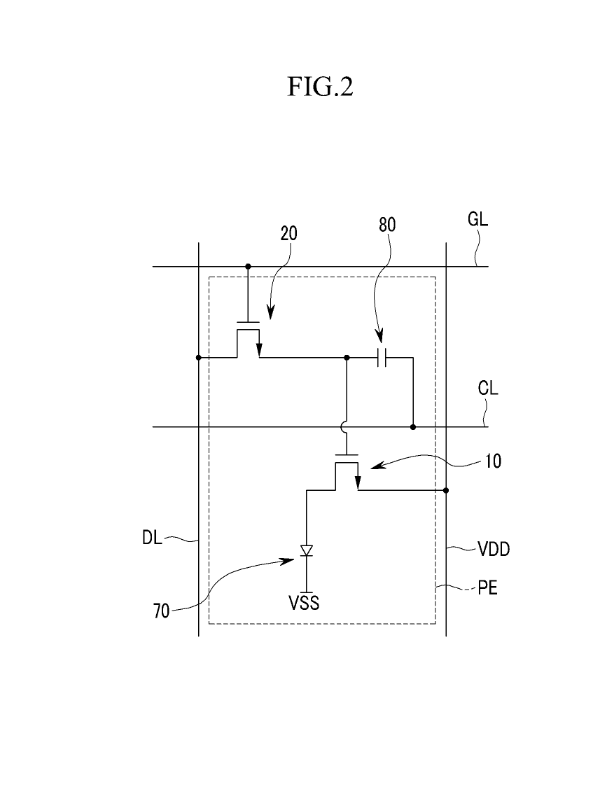

As shown in FIG. 2, the organic light emitting diode (OLED) display 101 has a 2Tr-1Cap structure in which an organic light emitting diode 70, two thin film transistors (TFT) 10 and 20, and a capacitor 80 are disposed in a single pixel area (PE). However, the OLED display 101 is not limited to this structure. Therefore, the organic light emitting diode (OLED) display 101 can have a configuration in which at least 3 thin film transistors and at least 2 capacitors are disposed in a single pixel area (PE), and can have various configurations with additional wiring. Accordingly, at least one of the additionally formed thin film transistors and capacitors can be an element of a compensation circuit.

The compensation circuit suppresses deviation of image quality by improving uniformity of the organic light emitting element 70 formed in each pixel area (PE). In general, the compensation circuit can include 2 to 8 thin film transistors.

Further, the driving circuits 910 and 920 (shown in FIG. 1) formed in the non-display area (NA) of the substrate main body 111 can include additional thin film transistors.

The organic light emitting element 70 includes an anode that is a hole injection electrode, a cathode that is electron injection electrode, and an organic emission layer disposed between the anode and the cathode.

In detail, the organic light emitting diode (OLED) display 101 includes a first thin film transistor 10 and a second thin film transistor 20 for each pixel area (PE). The first thin film transistor 10 and the second thin film transistor 20 respectively include a gate electrode, a polycrystalline semiconductor layer, a source electrode, and a drain electrode. The first thin film transistor 10 and the second thin film transistor 20 respectively include a polycrystalline semiconductor layer that is crystallized by a different method.

FIG. 2 shows a gate line (GL), a data line (DL), a common power line (VDD), and a capacitor line (CL). However, these elements are not restricted to the configuration of FIG. 2. Therefore, the capacitor line (CL) can be omitted in certain cases.

The source electrode of the second thin film transistor 20 is connected to the data line (DL), and the gate electrode of the second thin film transistor 20 is connected to the gate line (GL). The drain electrode of the second thin film transistor 20 is connected to the capacitor line (CL) through a capacitor 80. A node is formed between the drain electrode of the second thin film transistor 20 and the capacitor 80, and the gate electrode of the first thin film transistor 10 is connected thereto. The common power line (VDD) is connected to the drain electrode of the first thin film transistor 10, and the anode of the organic light emitting element 70 is connected to the source electrode of the common power line (VDD).

The second thin film transistor 20 is used as a switch for selecting the pixel area (PE) to emit light. When the second thin film transistor 20 is instantly turned on, the capacitor 80 is charged, and the quantity of electric charges in this instance is proportional to the potential of a voltage applied from the data line (DL). When a signal, the voltage of which is increased for each period of one frame, is input to the capacitor line (CL) while the second thin film transistor 20 is turned off, a gate potential of the first thin film transistor 10 rises according to the voltage that is applied through the capacitor line (CL) with the level of the voltage that is applied with reference to the potential charged in the capacitor 80. The first thin film transistor 10 is turned on when the gate potential exceeds a threshold voltage. The voltage applied to the common power line VDD is applied to the organic light emitting element 70 through the first thin film transistor 10, and the organic light emitting element 70 emits light.

The configuration of the pixel area (PE) is not restricted to the above description, and it may be modified in various different ways.

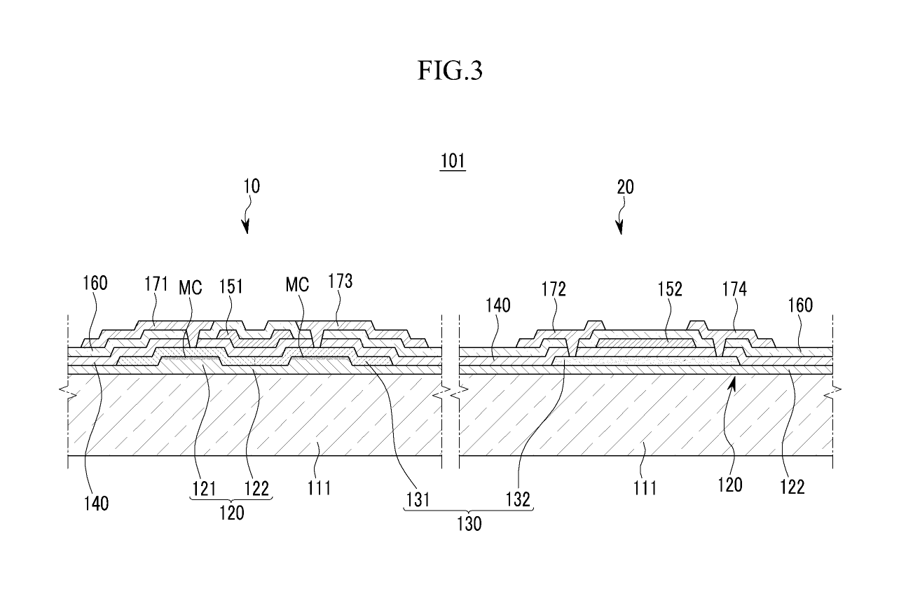

Configurations of the first thin film transistor 10 and the second thin film transistor 20 will now be described with reference to FIG. 3.

The substrate main body 111 is formed by a transparent insulating substrate made of glass, quartz, ceramic, and plastic. However, the substrate main body 111 is not restricted to this configuration, and the substrate main body 111 can be formed with a metallic substrate of stainless steel. Also, when the substrate main body 111 is made of plastic, it can be formed to be a flexible substrate.

An insulation layer pattern 120 is formed on the substrate main body 111. The insulation layer pattern 120 includes at least one of tetra ethyl ortho silicate (TEOS), silicon nitride, silicon dioxide, and silicon oxynitride. The insulation layer pattern 120 can function as a buffer layer. That is, the insulation layer pattern 120 can prevent permeation of unwanted components such as impurities or moisture.

Also, the insulation layer pattern 120 includes a first thickness layer 121 and a second thickness layer 122 that is thinner than the first thickness layer 121. A metal catalyst (MC) is scattered on the first thickness layer 121 of the insulation layer pattern 120. The metal catalyst (MC) includes at least one of nickel (Ni), palladium (Pd), titanium (Ti), silver (Ag), gold (Au), tin (Sn), antimony (Sb), copper (Cu), cobalt (Co), molybdenum (Mo), terbium (Tb), ruthenium (Ru), cadmium (Cd), and platinum (Pt). From among them, the desirable metal catalyst (MC) is nickel (Ni). Nickel disilicide (NiSi₂) generated by combination of nickel (Ni) and silicon (Si) efficiently boosts crystal growth.

Also, the metal catalyst (MC) is scattered on the first thickness layer 121 of the insulation layer pattern 120 with a dose amount within the range of 1.0e10 atoms/cm² to 1.0e14 atoms/cm². That is, a little metal catalyst (MC) is scattered by molecules on the first thickness layer 121 of the insulation layer pattern 120.

A polycrystalline semiconductor layer 130 is formed on the insulation layer pattern 120. The polycrystalline semiconductor layer 130 is divided into a first crystal area 131 and a second crystal area 132. The first crystal area 131 corresponds to the first thickness layer 121 of the insulation layer pattern 120 and the second thickness layer 122 near the first thickness layer 121. The first crystal area 131 is crystallized through the metal catalyst (MC) that is scattered on the first thickness layer 121 of the insulation layer pattern 120. On the other hand, the second crystal area 132 corresponds to the second thickness layer 122 of the insulation layer pattern 120. The second crystal area 132 is formed through solid phase crystallization (SPC).

In the solid phase crystallization (SPC) method silicon ions are injected into the deposited amorphous silicon layer and perform annealing below the temperature of 600° C. for at least several tens of hours. The final size of the grain depends on the dose amount, heating temperature, and heating time of the ion-injected silicon ions. The solid phase crystallized polycrystalline semiconductor layer 130 has grains of several μm, and the thin film transistor 20 using the same has relatively low leakage current. However, the solid phase crystallized polycrystalline semiconductor layer 130 has many defects in the grains, and the thin film transistor 20 using the same does not have a relatively great current driving performance, that is, electron mobility.

Also, the method for crystallization through the metal catalyst (MC) can crystallize the amorphous silicon layer at a relatively low temperature within a comparatively short time. For example, regarding the process for crystallizing the amorphous silicon layer by using the nickel (Ni) as the metal catalyst (MC), the nickel (Ni) is combined with the silicon (Si) of the amorphous silicon layer to become nickel disilicide (NiSi₂). The nickel disilicide (NiSi₂) becomes a seed, and the crystal grows with reference to it.

The polycrystalline semiconductor layer 130 that is crystallized through the metal catalyst (MC) has grains with a size of several tens of μm, and the size is greater than that of the grains of the solid phase crystallized polycrystalline semiconductor layer 130. Also, a plurality of sub-grain boundaries are given in one grain boundary. Therefore, deterioration of uniformity caused by the grain boundary is minimized.

Further, when the metal catalyst (MC) is disposed below the amorphous silicon layer and the crystal grows from among the methods of using the metal catalyst (MC), the grain boundary becomes dimmer and defects in the grain are reduced compared to the case in which the metal catalyst (MC) is disposed above the amorphous silicon layer.

In addition, the thin film transistor 10 using the polycrystalline semiconductor layer 130 that is crystallized through the metal catalyst (MC) has relatively high current driving performance, that is, electron mobility. However, it has a relatively high leakage current because of the metallic component remaining in the polycrystalline semiconductor layer 130.

The first crystal area 131 of the polycrystalline semiconductor layer 130 of the first thin film transistor 10 has relatively high current driving performance. Since the first thin film transistor 10 is connected to the organic light emitting element 70 to drive the organic light emitting element 70, high electron mobility is a characteristic of the thin film transistor 10. The second crystal area 132 of the polycrystalline semiconductor layer 130 of the second thin film transistor 20 has a relatively low leakage current. Hence, the organic light emitting diode (OLED) display 101 minimizes generation of unwanted leakage current.

As described, the polycrystalline semiconductor layer 130 having a plurality of crystal areas 131 and 132 that are crystallized by different methods according to usage can be efficiently formed in a single pixel area (PE) (shown in FIG. 2).

A gate insulating layer 140 is formed on the polycrystalline semiconductor layer 130. The gate insulating layer 140 is formed of one of tetra ethyl ortho silicate (TEOS), silicon nitride (SiNx), and silicon dioxide (SiO₂) or mixtures thereof. For example, the gate insulating layer 140 can be formed with a double layered structure in which a silicon nitride film with the thickness of 40 nm and a tetra ethyl ortho silicate film with the thickness of 80 nm are sequentially stacked. However, the gate insulating layer 140 is not limited to the above-described configuration.

Gate electrodes 151 and 152 are formed on the gate insulating layer 140. The gate electrodes 151 and 152 are disposed to be overlapped with a part of the polycrystalline semiconductor layer 130. That is, the gate electrodes 151 and 152 are disposed to be separated from the polycrystalline semiconductor layer 130 with the gate insulating layer 140 therebetween. The gate electrode 151 and 152 can include at least one of molybdenum (Mo), chromium (Cr), aluminum (Al), silver (Ag), titanium (Ti), tantalum (Ta), and tungsten (W).

The gate electrode includes a first gate electrode 151 used for the first thin film transistor 10 and a second gate electrode 152 used for the second thin film transistor 20.

An interlayer insulating layer 160 is formed on the gate electrodes 151 and 152. The interlayer insulating layer 160 can be formed of tetra ethyl ortho silicate (TEOS), silicon nitride (SiNx), or silicon dioxide (SiOx) in a like manner of the gate insulating layer 140, but is not limited thereto.

The interlayer insulating layer 160 and the gate insulating layer 140 have contact holes for revealing a part of the polycrystalline semiconductor layer 130.

Source electrodes 171 and 172 and drain electrodes 173 and 174 respectively connected to the polycrystalline semiconductor layer 130 through the contact holes are formed on the interlayer insulating layer 160. The source electrodes 171 and 172 and the drain electrodes 173 and 174 are separately disposed. Also, the source electrodes 171 and 172 and the drain electrodes 173 and 174 are separately disposed from the gate electrodes 151 and 152 with an interlayer insulating layer therebetween. The source electrodes 171 and 172 and the drain electrodes 173 and 174 can include at least one of molybdenum (Mo), chromium (Cr), aluminum (Al), silver (Ag), titanium (Ti), tantalum (Ta), and tungsten (W) in a like manner of the gate electrodes 151 and 152.

The source electrodes and the drain electrodes include a first source electrode 171 and a first drain electrode 173 used for the first thin film transistor 10, and a second source electrode 172 and a second drain electrode 174 used for the second thin film transistor 20.

According to the above-described configuration, the organic light emitting diode (OLED) display 101 has a polycrystalline semiconductor layer 130 including a plurality of crystal areas 131 and 132 that are crystallized in a single pixel area (PE) (shown in FIG. 2) by different methods according to usage. A plurality of thin film transistors 10 and 20 with different characteristics can be formed in the pixel area (PE) by using the polycrystalline semiconductor layer 130.

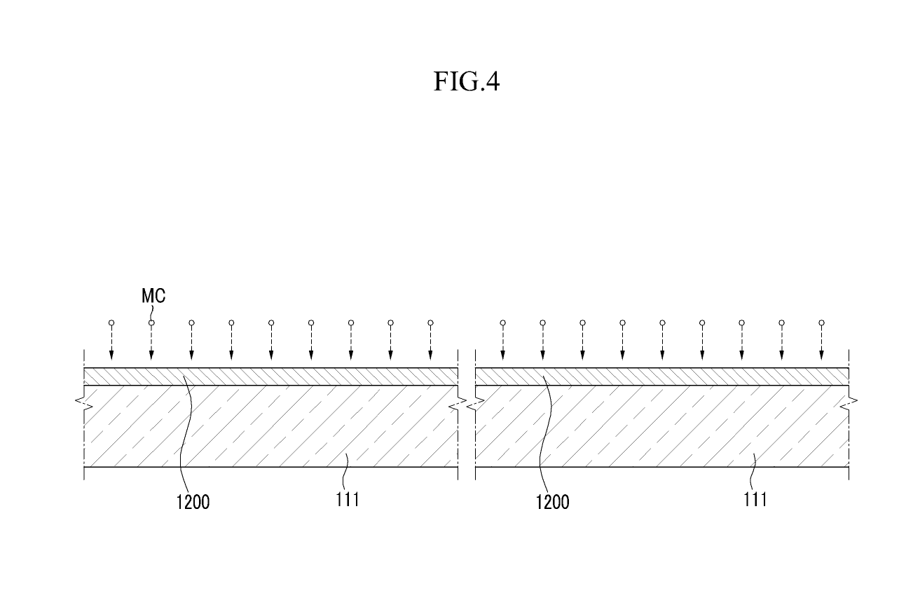

A method of manufacturing the organic light emitting diode (OLED) display 101 illustrated in FIG. 3 will now be described with reference to FIG. 4 to FIG. 10.

First, as shown in FIG. 4, an insulation layer 1200 is formed on the substrate main body 111. The insulation layer 1200 includes at least one of tetra ethyl ortho silicate (TEOS), silicon nitride, silicon dioxide, and silicon oxynitride.

A metal catalyst (MC) is scattered on the insulation layer 1200. In this instance, the metal catalyst (MC) is scattered with an amount of dose within the range of 1.0e10 atoms/cm² to 1.0e14 atoms/cm². That is, a small amount of the metal catalyst (MC) is scattered by molecules on the insulation layer.

Also, the metal catalyst (MC) can include at least one of nickel (Ni), palladium (Pd), titanium (Ti), silver (Ag), gold (Au), tin (Sn), antimony (Sb), copper (Cu), cobalt (Co), molybdenum (Mo), terbium (Tb), ruthenium (Ru), cadmium (Cd), and platinum (Pt). Nickel (Ni) is used as the metal catalyst (MC) in FIG. 4.

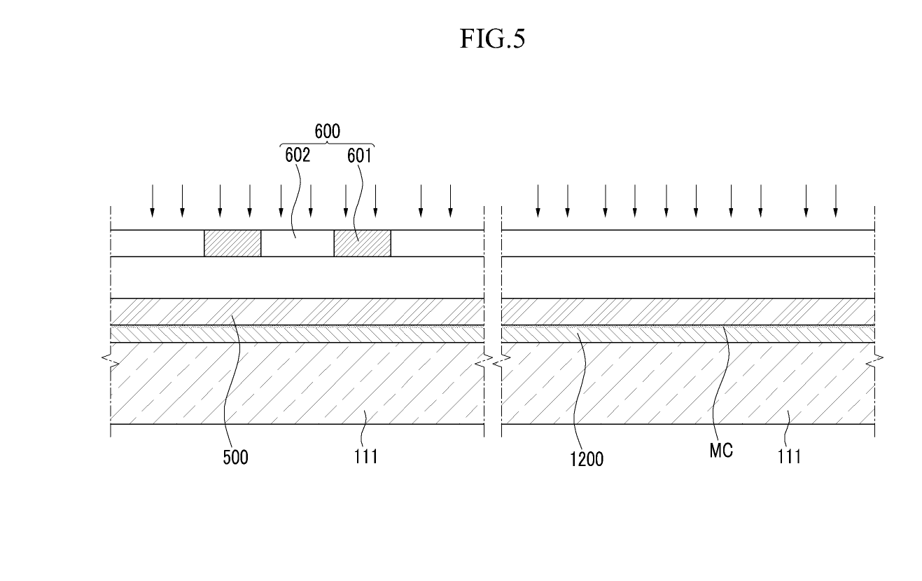

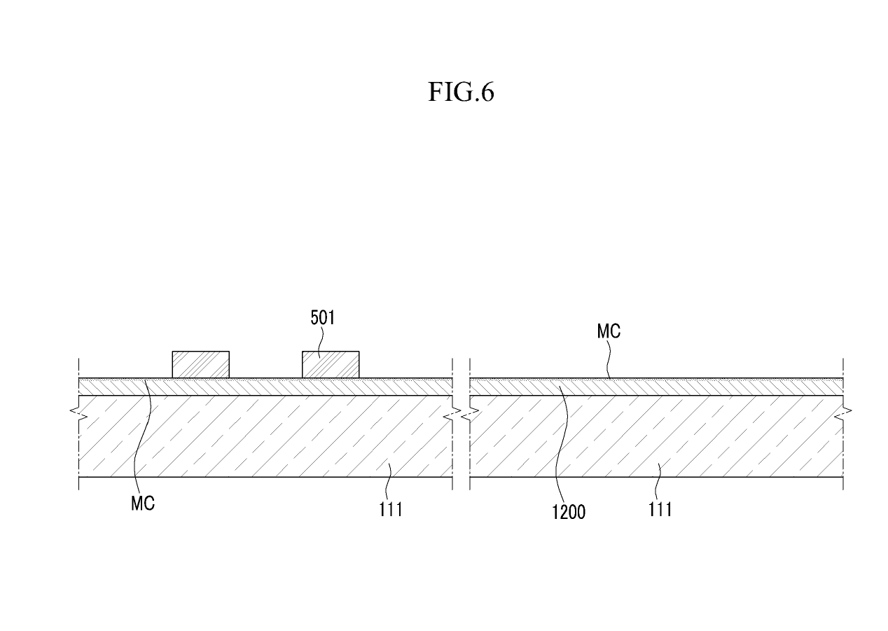

Next, as shown in FIG. 5, a photoresist organic film 500 is coated on the insulation layer 1200 on which the metal catalyst (MC) is scattered, and an exposure process is performed by using a mask 600. Here, the mask 600 includes a light shielder 601 and a light transmitter 602. A photoresist pattern 501 shown in FIG. 6 is formed by developing the exposed photoresist organic film 500.

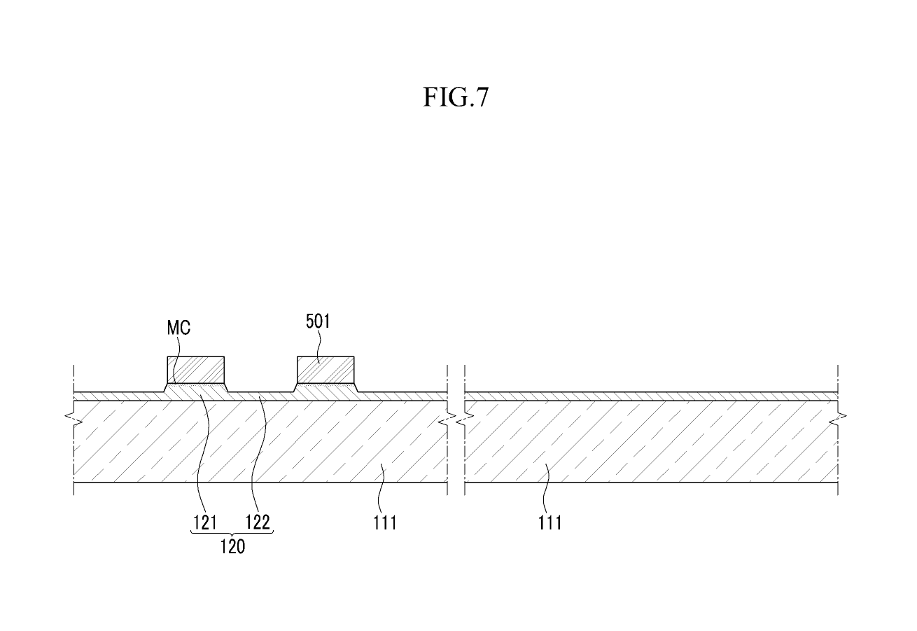

Next, as shown in FIG. 7, an insulation layer pattern 120 is formed by partially etching the insulation layer 1200 on which metal catalyst (MC) is scattered by using the photoresist pattern 501. The insulation layer pattern 120 includes a first thickness layer 121 and a second thickness layer 122 that is relatively thinner than the first thickness layer 121. In this instance, the first thickness layer 121 of the insulation layer pattern 120 has a surface layer on which the metal catalyst (MC) is scattered, and the second thickness layer 122 of the insulation layer pattern 120 loses the surface layer on which the metal catalyst (MC) is scattered.

Also, as described above, the process for forming the insulation layer pattern 120 by patterning the insulation layer 1200 is called a photolithography process.

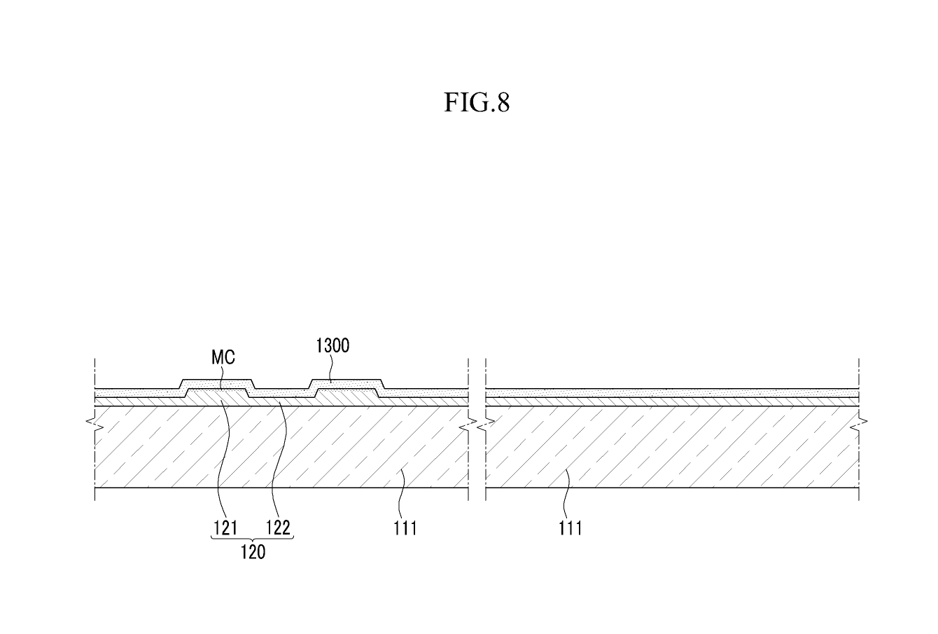

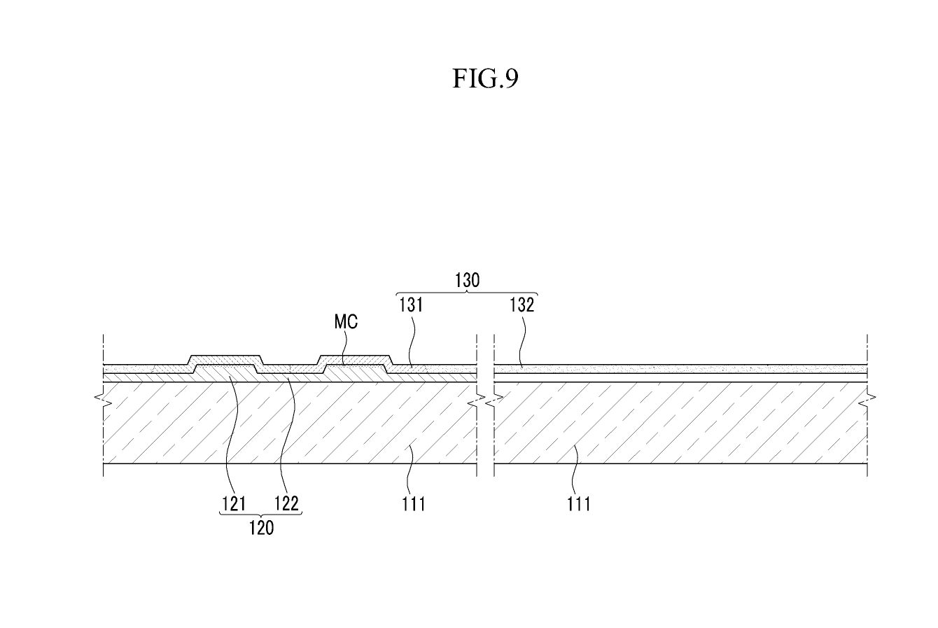

Next, a remaining photoresist pattern 501 is eliminated, and as shown in FIG. 8, an amorphous silicon layer 1300 is formed on the insulation layer pattern 120. The amorphous silicon layer 1300 is crystallized to form a polycrystalline semiconductor layer 130 as shown in FIG. 9.

The polycrystalline semiconductor layer 130 is divided into a first crystal area 131 corresponding to the first thickness layer 121 of the insulation layer pattern 120 and the second thickness layer 122 near the first thickness layer 121, and a second crystal area 132 corresponding to the other second thickness layer 122 of the insulation layer pattern 120. Here, the first crystal area 131 is crystallized through the metal catalyst (MC), and the second crystal area 132 is solid phase crystallized. In detail, when the amorphous silicon layer 1300 formed on the insulation layer pattern 140 according to the first exemplary embodiment is heated, the metal catalyst (MC) that is scattered on the first thickness layer 141 of the insulation layer pattern 140 is operated to grow crystal. The other amorphous silicon layer 1300 that is separated from the first thickness layer 141 of the insulation layer pattern 140 by more than a predetermined gap and is not influenced by the metal catalyst (MC) is solid phase crystallized by heat.

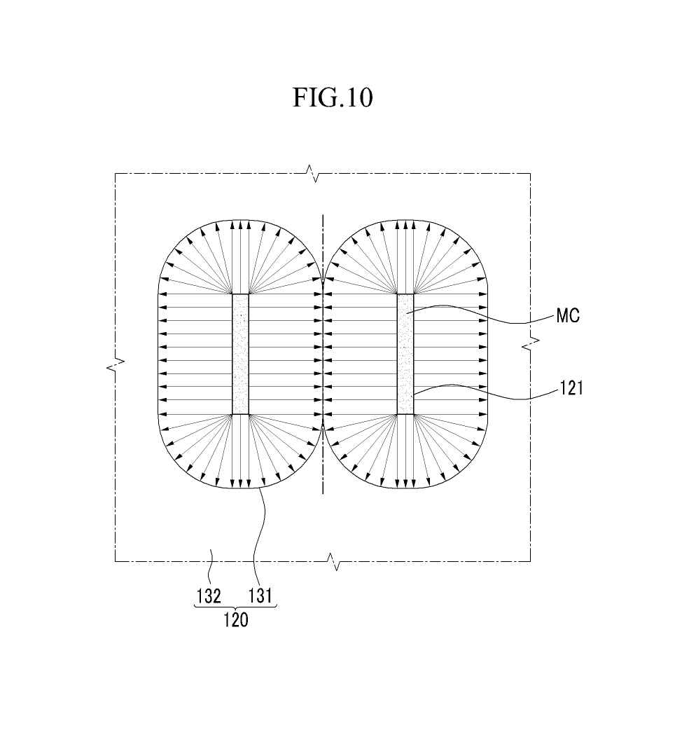

FIG. 10 shows a grain boundary of the first crystal area 131 crystallized by the metal catalyst (MC). The arrows in FIG. 10 indicate the direction in which the crystal grows by the metal catalyst (MC) with reference to the first thickness layer 121 of the insulation layer pattern 120. Also, an area outside the grain boundary of the first crystal area 131 becomes a solid phase crystallized second crystal area 132.

As shown in FIG. 10, the first crystal area 131 that is crystallized by the metal catalyst (MC) that is scattered on the first thickness layer 121 of the insulation layer pattern 120 can be partially formed. Therefore, the polycrystalline semiconductor layer 130 including the first crystal area 131 and the second crystal area 132 that are crystallized in a single pixel area (PE) (shown in FIG. 2) by different methods can be efficiently formed.

As shown in FIG. 3, gate electrodes 151 and 152, source electrodes 171 and 172, and drain electrodes 173 and 174 are formed to form the first thin film transistor 10 and the second thin film transistor 20.

Through the above-noted manufacturing method, the organic light emitting diode (OLED) display 101 can be manufactured. That is, the first thin film transistor 10 and the second thin film transistor 20 having different characteristics can be simultaneously and efficiently formed in the single pixel area (PE) (shown in FIG. 2).

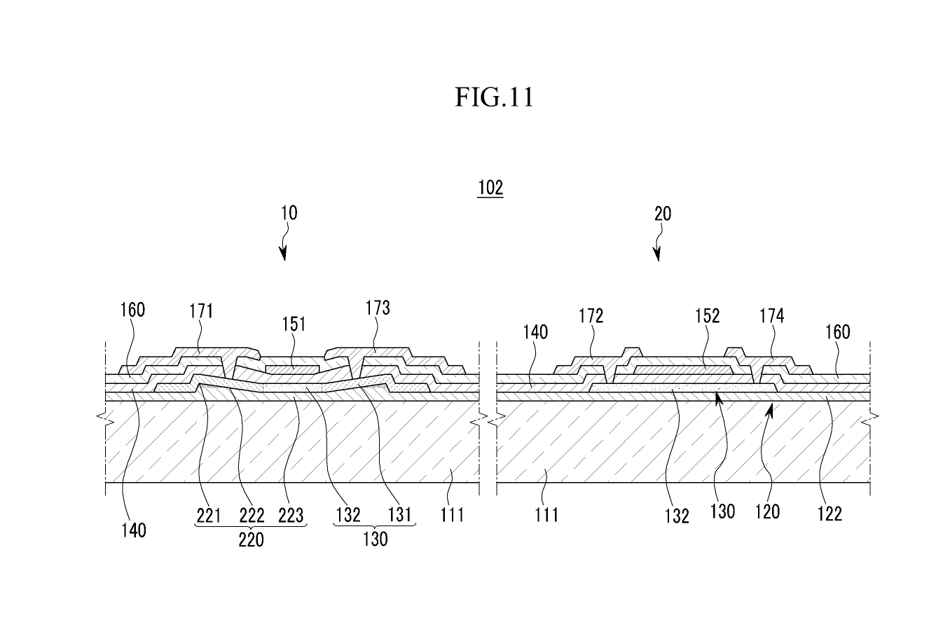

Referring to FIG. 11, an organic light emitting diode (OLED) display 102 according to another embodiment will now be described.

As shown in FIG. 11, an insulation layer pattern 220 of the organic light emitting diode (OLED) display 102 includes a first thickness layer 221, a gradient thickness layer 222, and a second thickness layer 223. The first thickness layer 221 is relatively the thickest part, and the second thickness layer 223 is relatively the thinnest part. The gradient thickness layer 222 represents a part of which thickness is gradually decreased from the first thickness layer 221 to the second thickness layer 223. That is, the gradient thickness layer 222 has a sloped cross-section.

Also, a metal catalyst (MC) such as nickel (Ni) is scattered on a part of the gradient thickness layer 222 and the first thickness layer 221. In this instance, the metal catalyst (MC) is scattered with a dose amount within the range of 1.0e10 atoms/cm² to 1.0e14 atoms/cm². That is, a small amount of the metal catalyst (MC) is scattered by molecules in the least size on the first thickness layer 221 and a part of the gradient thickness layer 222 of the insulation layer pattern 220. As the thickness of the gradient thickness layer 222 becomes thinner, concentration of the metal catalyst (MC) that is scattered on the surface layer is gradually reduced, and when the thickness thereof becomes less than a predetermined thickness approaching the second thickness layer 223, the metal catalyst (MC) is no longer present on the surface layer.

The polycrystalline semiconductor layer 130 formed on the insulation layer pattern 220 is divided into a first crystal area 131 and a second crystal area 132. The first crystal area 131 corresponds to the first thickness layer 221, the gradient thickness layer 222, and a portion of the second thickness layer 223 of the insulation layer pattern 220. The first crystal area 131 is crystallized through the metal catalyst (MC) that is scattered on the first thickness layer 221 and the gradient thickness layer 222 of the insulation layer pattern 220. The second crystal area 132 corresponds to the remaining portion of the second thickness layer 223 of the insulation layer pattern 220. The second crystal area 132 is solid phase crystallized.

Also, growth of the first crystal area 131 is controlled by the gradient thickness layer 222 of the insulation layer pattern 220. For a gentle gradient of the gradient thickness layer 222, growth of the first crystal area 131 is relatively reduced, and for a steep gradient of the gradient thickness layer 222, growth of the first crystal area 131 is relatively expanded. Therefore, when it is needed to suppress extension of the first crystal area 131 of the polycrystalline semiconductor layer 130 in a predetermined direction with reference to the first thickness layer 221 of the insulation layer pattern 220, the gradient thickness layer 222 needs to be formed in the same direction with a gentle gradient.

Accordingly growth of the first crystal area 131 of the polycrystalline semiconductor layer 130 can be efficiently and precisely controlled in the single pixel area (PE) (shown in FIG. 2) and a relatively narrow area.

Through the above-noted configuration, the organic light emitting diode (OLED) display 102 includes the polycrystalline semiconductor layer 130 having a plurality of crystal areas 131 and 132 that are crystallized by different methods in the single pixel area (PE) (shown in FIG. 2) according to usage, and can include a plurality of thin film transistors 10 and 20 with different characteristics in the single pixel area (PE) by using the polycrystalline semiconductor layer 130.

Also, since the insulation layer pattern 220 can precisely control the growth of the first crystal area 131 by the gradient thickness layer 222, the respective parts of the polycrystalline semiconductor layer 130 used for one thin film transistor 10 can be effectively easily crystallized by using different methods.

In detail, at least a part of the polycrystalline semiconductor layer 130 overlapped on the first gate electrode 151 of the first thin film transistor 10 can be the second crystal area 132. That is, a part of the polycrystalline semiconductor layer 130 overlapped on the first gate electrode 151 can be formed to be the second crystal area 132 while the first thin film transistor 10 uses the first crystal area 131.

Accordingly, when the first gate electrode 151 is overlapped on the second crystal area 131 of the polycrystalline semiconductor layer 130, the metal catalyst (MC) provided near the first gate electrode 151 is reduced to thus decrease some leakage current of the first thin film transistor 10.

In the embodiment illustrated in FIG. 3, the first crystal area 131 of the polycrystalline semiconductor layer 130 overlapped on the first gate electrode 151 of the first thin film transistor 10 and the second crystal area 132 overlapped on the second gate electrode 152 of the second thin film transistor 20 in a like manner of the embodiment illustrated in FIG. 11.

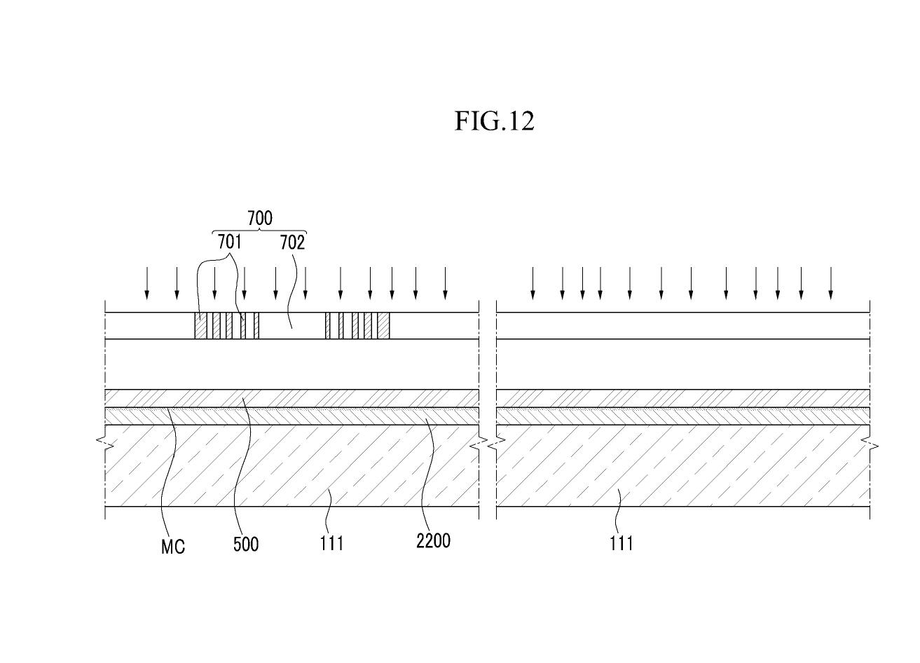

Referring to FIG. 12 to FIG. 16, a method for manufacturing an organic light emitting diode (OLED) display 102 according to the embodiment illustrated in FIG. 11 will now be described.

First, as shown in FIG. 12, an insulation layer 2200 is formed on the substrate main body 111, and the metal catalyst (MC) such as nickel (Ni) is scattered on the insulation layer 2200.

Next, a photoresist organic film 500 is coated on the insulation layer 2200 on which the metal catalyst (MC) is scattered, and an exposure process is performed by using a mask 700. Here, the mask 700 includes a light shield 701 and a light transmitter 702. Also, the light shield 701 of the mask 700 includes a part for gradually controlling exposure. For example, the mask 700 can have a slit pattern with a gap that varies gradually.

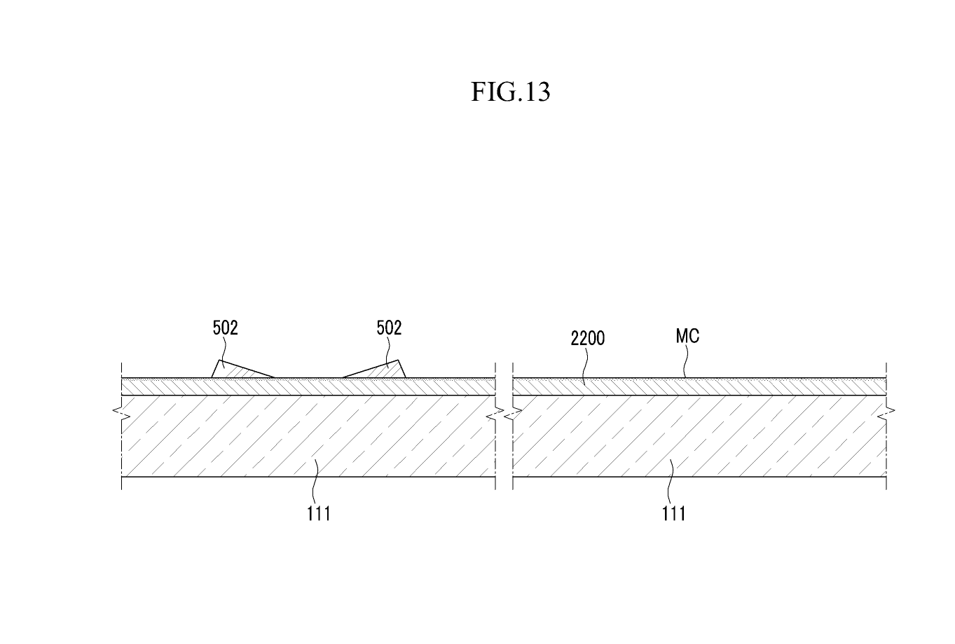

Next, as shown in FIG. 13, the exposed photoresist organic film 500 is developed to form a photoresist pattern 502. In this instance, the photoresist pattern 502 is formed in a gradient structure.

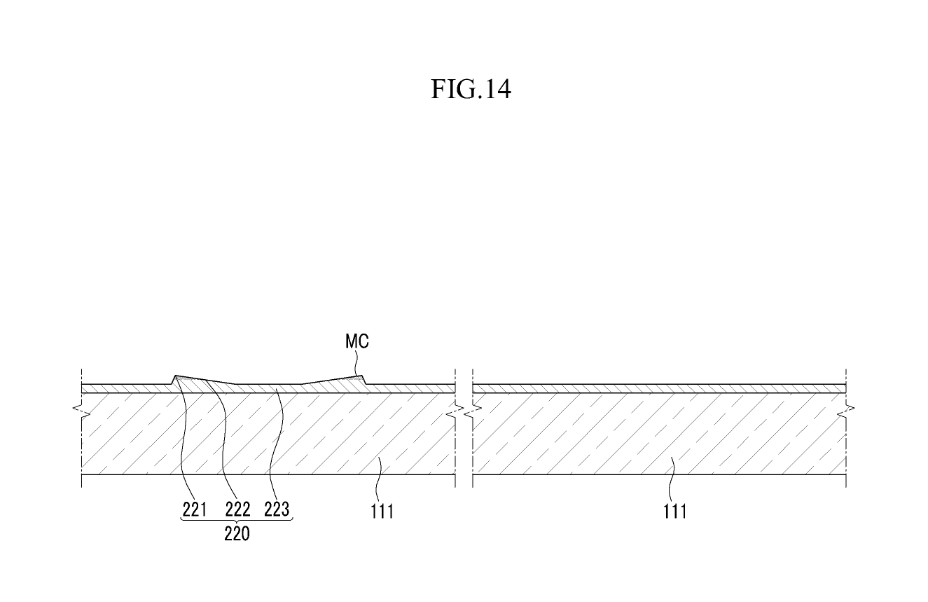

As shown in FIG. 14, when the insulation layer 2200 on which the metal catalyst (MC) is scattered is partially etched by using the gradient-structured photoresist pattern 502 and the remaining photoresist pattern 502 is removed, an insulation layer pattern 220 is formed. In detail, the insulation layer pattern 220 includes the first thickness layer 221 that is relatively the thickest, the second thickness layer 223 that is relatively the thinnest, and the gradient thickness layer 222 with a thickness that is gradually decreased from the thickness of the first thickness layer 221 to that of the second thickness layer 223. In this instance, the first thickness layer 221 of the insulation layer pattern 220 has the surface layer on which the metal catalyst (MC) is scattered, and the second thickness layer 223 of the insulation layer pattern 220 loses the surface layer on which the metal catalyst (MC) is scattered. Also, as the thickness of the gradient thickness layer 222 becomes thinner, concentration of the metal catalyst (MC) that is scattered on the surface layer is reduced, and when the thickness becomes less than a predetermined thickness that is near that of the second thickness layer 223, the metal catalyst (MC) does not substantially exist on the surface layer.

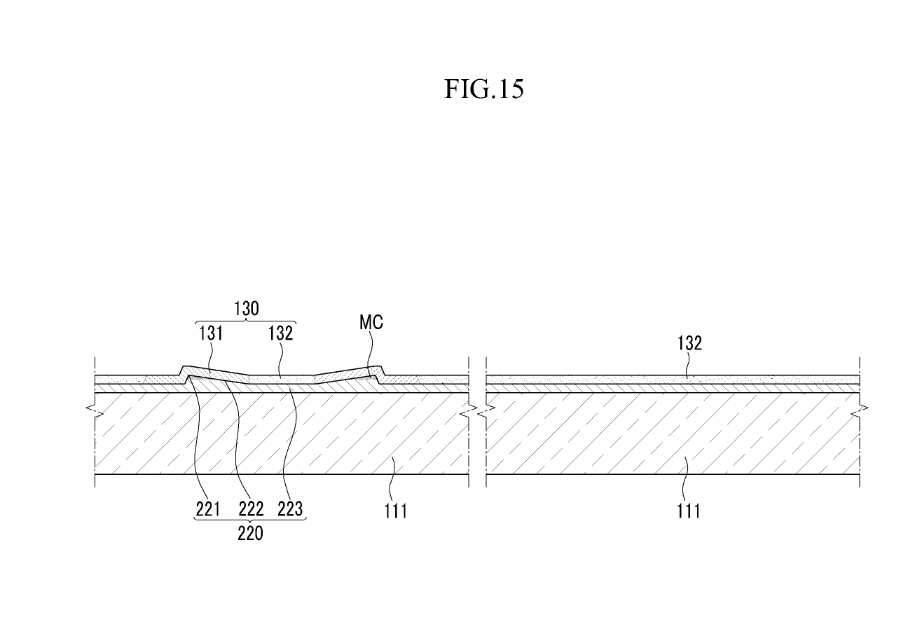

As shown in FIG. 15, when an amorphous silicon layer is formed on the insulation layer pattern 220, it is crystallized to form the polycrystalline semiconductor layer 130.

The polycrystalline semiconductor layer 130 includes a first crystal area 131 and a second crystal area 132. The first crystal area 131 covers the first thickness layer 221, the gradient thickness layer 222 and a portion of the second thickness layer 223 of the insulation layer pattern 220. The second crystal area 132 covers a remaining portion of the second thickness layer 223 adjacent to the layers 221 and 222 of the insulation layer pattern 220. Here, the first crystal area 131 is crystallized through the metal catalyst (MC), and the second crystal area 132 is solid phase crystallized. In detail, when the amorphous silicon layer that is formed on the insulation layer pattern 220 is heated, the metal catalyst (MC) that is scattered on the first thickness layer 221 and the gradient thickness layer 222 of the insulation layer pattern 220 works to perform crystallization. The other amorphous silicon layer that is separated from the first thickness layer 221 of the insulation layer pattern 220 by greater than a predetermined distance and is not influenced by the metal catalyst (MC) is solid phase crystallized by heat.

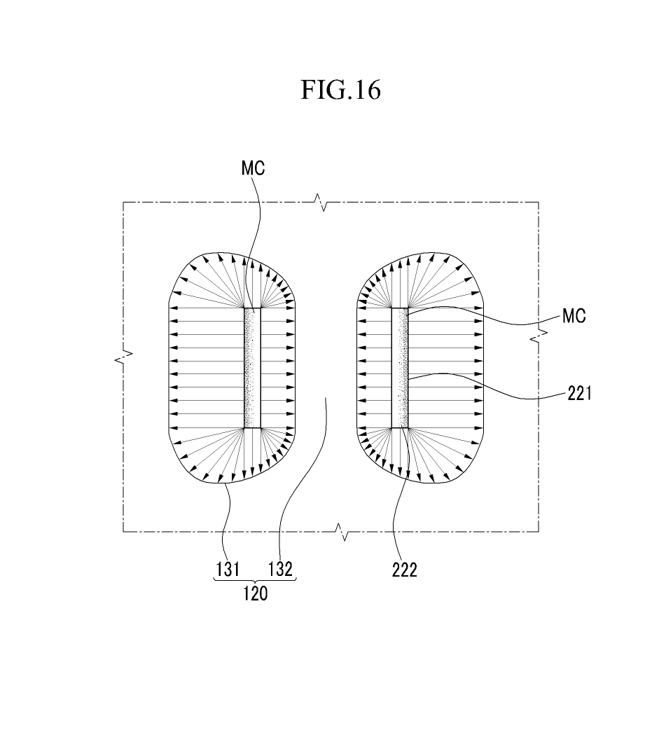

FIG. 16 shows a grain boundary of the first crystal area 131 that is crystallized by the metal catalyst (MC). In FIG. 16, the arrows show a direction in which the crystal grows by the work of the metal catalyst (MC) with reference to the first thickness layer 221 of the insulation layer pattern 220. Also, the area outside the grain boundary of first crystal area 131 becomes the solid phase crystallized second crystal area 132.

As shown in FIG. 16, the first crystal area 131 that is crystallized by the metal catalyst (MC) that is scattered on the first thickness layer 221 and a part of the gradient thickness layer 222 of the insulation layer pattern 220 can be partially formed. Therefore, the polycrystalline semiconductor layer 130 including the first crystal area 131 and the second crystal area 132 that are crystallized in the single pixel area (PE) (shown in FIG. 2) by different methods can be efficiently formed.

Also, growth of the first crystal area 131 is controllable by the gradient thickness layer 222 of the insulation layer pattern 220. As shown in FIG. 11 and FIG. 16, for a gentle gradient of the gradient thickness layer 222, growth of crystal is reduced, and for a steep gradient of the gradient thickness layer 222, the growth of crystal is expanded. Therefore, the first crystal area 131 can be formed more precisely by using the gradient thickness layer 222 of the insulation layer pattern 220. The plurality of thin film transistors 10 and 20 including the polycrystalline semiconductor layer 130 crystallize by different methods according to usage in a relatively narrow area such as the pixel area (PE) (shown in FIG. 2). Also, the parts of the polycrystalline semiconductor layer 330 used for one thin film transistor 10 can be efficiently crystallized by using other methods.

Next, as shown in FIG. 11, the first thin film transistor 10 and the second thin film transistor 20 are formed by forming the gate electrodes 151 and 152, source electrodes 171 and 172, and drain electrodes 173 and 174. In this instance, the first gate electrode 151 of the first thin film transistor 10 can be partially overlapped on the second crystal area 132 of the polycrystalline semiconductor layer 130.

Through the above-described manufacturing method, the organic light emitting diode (OLED) display 102 can be manufactured. That is, the first thin film transistor 10 and the second thin film transistor 20 having different characteristics can be simultaneously and efficiently formed in the single pixel area (PE) (shown in FIG. 2).

Further, since growth of the first crystal area 131 can be precisely controlled through the gradient thickness layer 222 of the insulation layer pattern 220, the part of the polycrystalline semiconductor layer 130 used for one thin film transistor 10 can be efficiently crystallized by different methods.

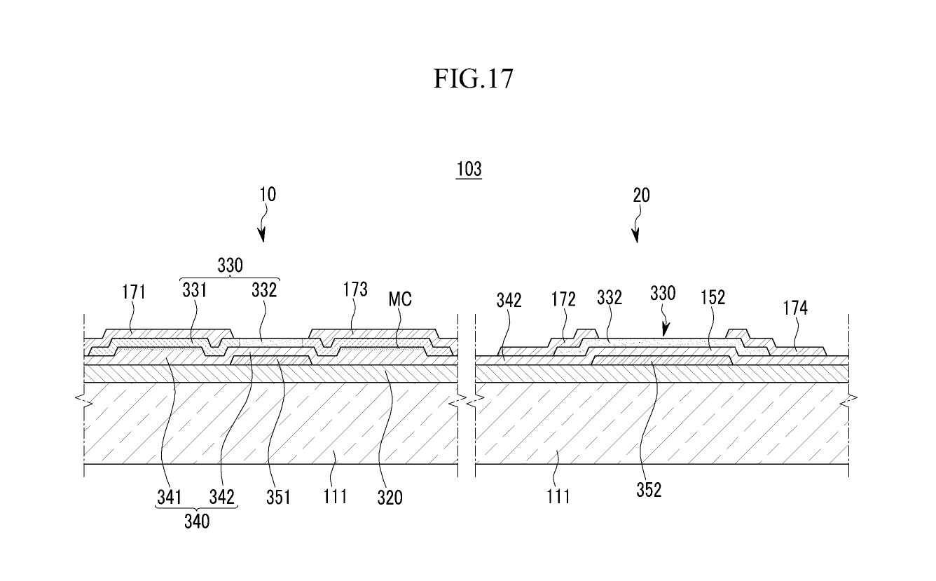

Referring to FIG. 17, an organic light emitting diode (OLED) display 103 according to another embodiment can be described.

As shown in FIG. 17, the organic light emitting diode (OLED) display 103 forms a buffer layer 320 on the substrate main body 111. For example, the buffer layer 320 can be formed in a single film structure of silicon nitride (SiNx) or a double film structure of silicon nitride (SiNx) and silicon dioxide SiO₂. The buffer layer 320 prevents permeation of unwanted components such as impurities or moisture, and smoothes the surface. However, the buffer layer 320 does not need to be included in the configuration, and can be omitted depending on the type and process conditions of the substrate main body 111.

Gate electrodes 351 and 352 are formed on the buffer layer 320. An insulation layer pattern 340 is formed on the gate electrodes 351 and 352. The insulation layer pattern 340 includes at least one of tetra ethyl ortho silicate (TEOS), silicon nitride, silicon dioxide, and silicon oxynitride.

The gate electrodes include a first gate electrode 351 used for the first thin film transistor 10 and a second gate electrode 352 used for the second thin film transistor 20.

In addition, the insulation layer pattern 340 includes a first thickness layer 341 and a second thickness layer 342 that is thinner than the first thickness layer 341. A metal catalyst (MC) such as nickel (Ni) is scattered on the first thickness layer 341 of the insulation layer pattern 340.

Also, the metal catalyst (MC) is scattered on the first thickness layer 341 of the insulation layer pattern 340 with an amount of dose within the range of 1.0e10 atoms/cm² to 1.0e14 atoms/cm². That is, a little metal catalyst (MC) is scattered by molecules on the first thickness layer 341 of the insulation layer pattern 340.

A polycrystalline semiconductor layer 330 is formed on the insulation layer pattern 340. The polycrystalline semiconductor layer 330 is divided into a first crystal area 331 and a second crystal area 332. The first crystal area 331 corresponds to the first thickness layer 341 of the insulation layer pattern 340 and the second thickness layer 342 near the first thickness layer 341. The first crystal area 331 is crystallized through the metal catalyst (MC) that is scattered on the first thickness layer 341 of the insulation layer pattern 340. On the other hand, the second crystal area 332 corresponds to the second thickness layer 342 of the insulation layer pattern 340. The second crystal area 332 is formed through solid phase crystallization (SPC).

The metal catalyst (MC) is disposed under the polycrystalline semiconductor layer 330 and works for crystallization.

Accordingly, the polycrystalline semiconductor layer 330 having a plurality of crystal areas 331 and 332 that are crystallized by different methods according to usage can be efficiently formed in a single pixel area (PE) (shown in FIG. 2).

The source electrodes 171 and 172 and the drain electrodes 173 and 174 connected to a part of the polycrystalline semiconductor layer 130 are formed on the polycrystalline semiconductor layer 330. The source electrodes 171 and 172 and the drain electrode 173 and 174 are separately disposed.

The source electrodes and the drain electrodes include the first source electrode 171 and the first drain electrode 173 used for the first thin film transistor 10, and the second source electrode 172 and the second drain electrode 174 used for the second thin film transistor 20.

The first thin film transistor 10 can have relatively high current driving performance by partially using the first crystal area 331 of the polycrystalline semiconductor layer 330. The second thin film transistor 20 uses the second crystal area 332 of the polycrystalline semiconductor layer 330. Hence, the second thin film transistor 20 has a relatively low leakage current.

However, since at least part of the first gate electrode 351 of the first thin film transistor 10 is overlapped on the second crystal area 332 of the polycrystalline semiconductor layer 330, the leakage current of the first thin film transistor 10 can be somewhat reduced.

Accordingly, part of the polycrystalline semiconductor layer 330 used for the single thin film transistor 10 can be crystallized by different methods.

According to the above-described configuration, the organic light emitting diode (OLED) display 103 can form the polycrystalline semiconductor layer 330 having a plurality of crystal areas 331 and 332 that are crystallized by different methods according to usage in the single pixel area (PE) (shown in FIG. 2). A plurality of thin film transistors 10 and 20 having different characteristics can be formed in the single pixel area (PE) by using the polycrystalline semiconductor layer 330.

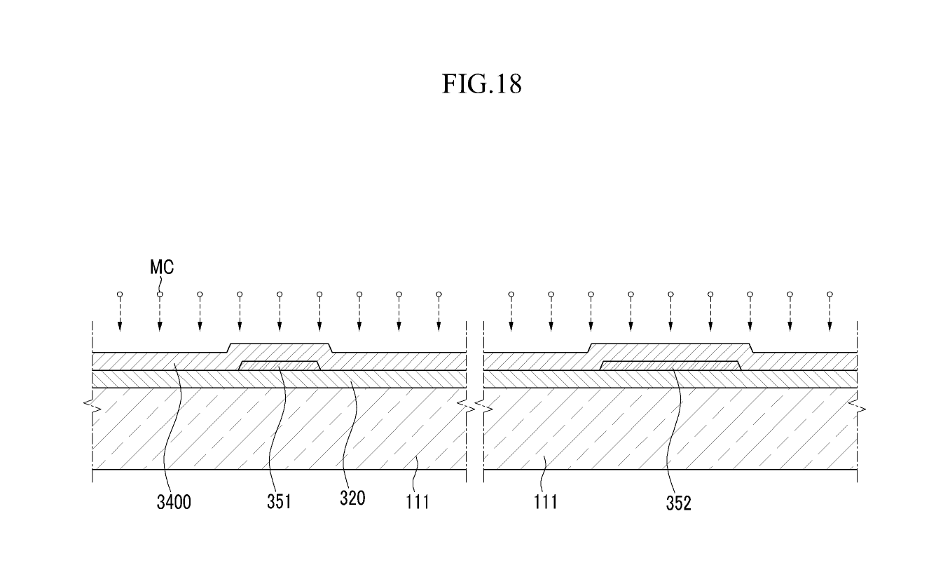

Referring to FIG. 18 to FIG. 21, a method for manufacturing the organic light emitting diode (OLED) display 103 according to the embodiment illustrated in FIG. 17 will now be described.

As shown in FIG. 18, a buffer layer 320 is formed on a substrate main body 111. A first gate electrode 351 and a second gate electrode 352 are formed on the buffer layer 320.

An insulation layer 3400 for covering the first gate electrode 351 and the second gate electrode 352 is formed. The insulation layer 3400 includes at least one of tetra ethyl ortho silicate (TEOS), silicon nitride, silicon dioxide, and silicon oxynitride.

The metal catalyst (MC) such as nickel (Ni) is scattered on the insulation layer 3400. In this instance, the metal catalyst (MC) is scattered with an amount of dose within the range of 1.0e10 atoms/cm² to 1.0e14 atoms/cm². That is, a small amount of the metal catalyst (MC) is scattered by molecules on the insulation layer.

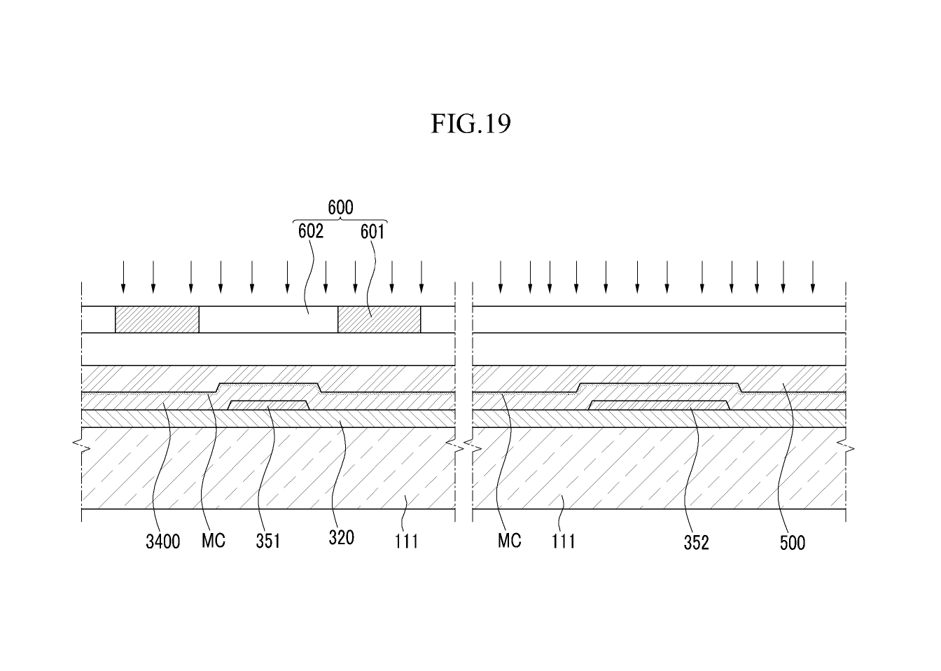

As shown in FIG. 19, a photoresist organic film 500 is coated on the insulation layer 3400 on which the metal catalyst (MC) is scattered, and an exposure process is performed by using the mask 600. Here, the mask 600 includes a light shielder 601 and a light transmitter 602.

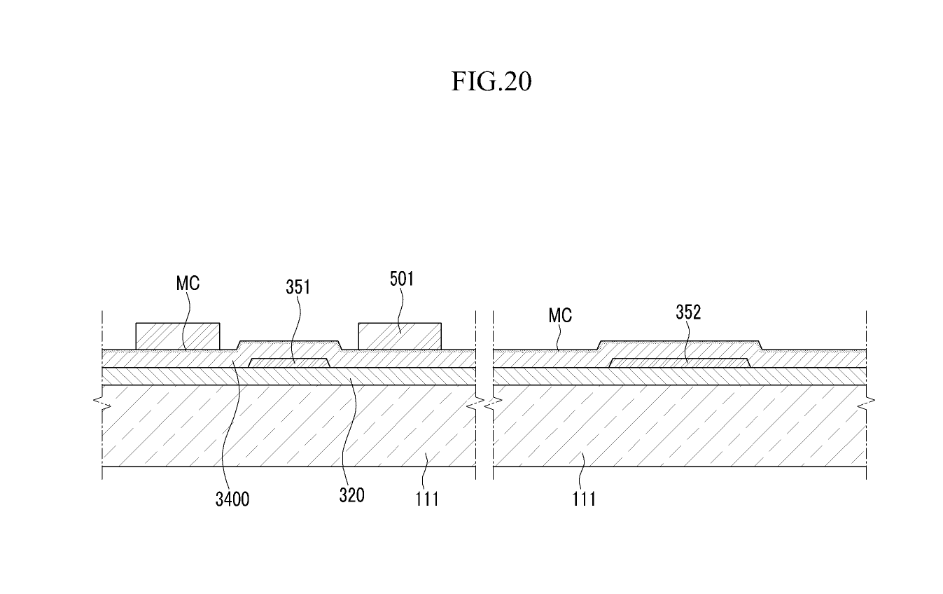

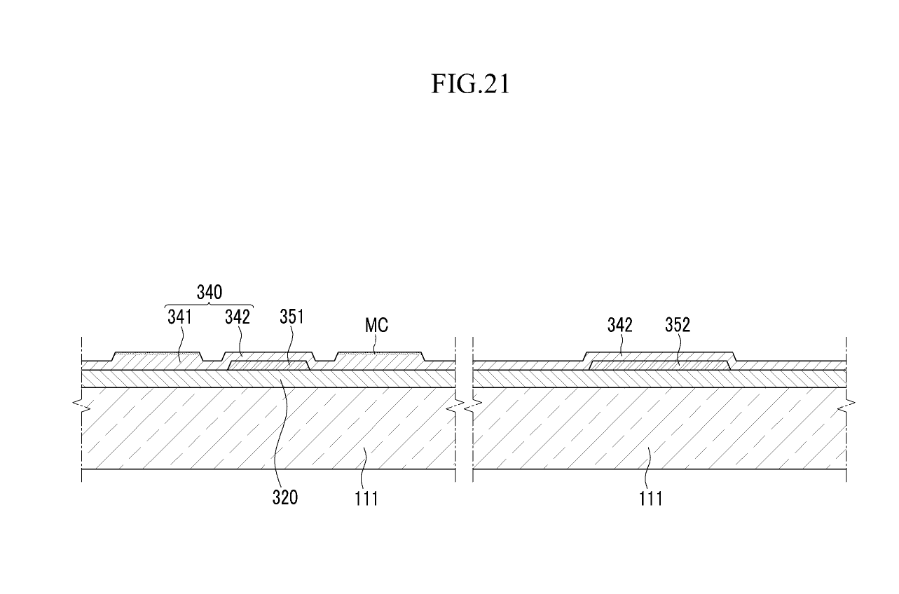

As shown in FIG. 20, a photoresist pattern 501 is formed by developing the exposed photoresist organic film 500. The insulation layer 3400 on which the metal catalyst (MC) is scattered is partially etched by using the photoresist pattern 501 to form the insulation layer pattern 340 shown in FIG. 21. The insulation layer pattern 340 includes a first thickness layer 341 and a second thickness layer 342 that is relatively thinner than the first thickness layer 341. In this instance, the first thickness layer 341 of the insulation layer pattern 340 has the surface layer on which the metal catalyst (MC) is scattered, and the second thickness layer 342 of the insulation layer pattern 340 loses the surface layer on which the metal catalyst (MC) is scattered.

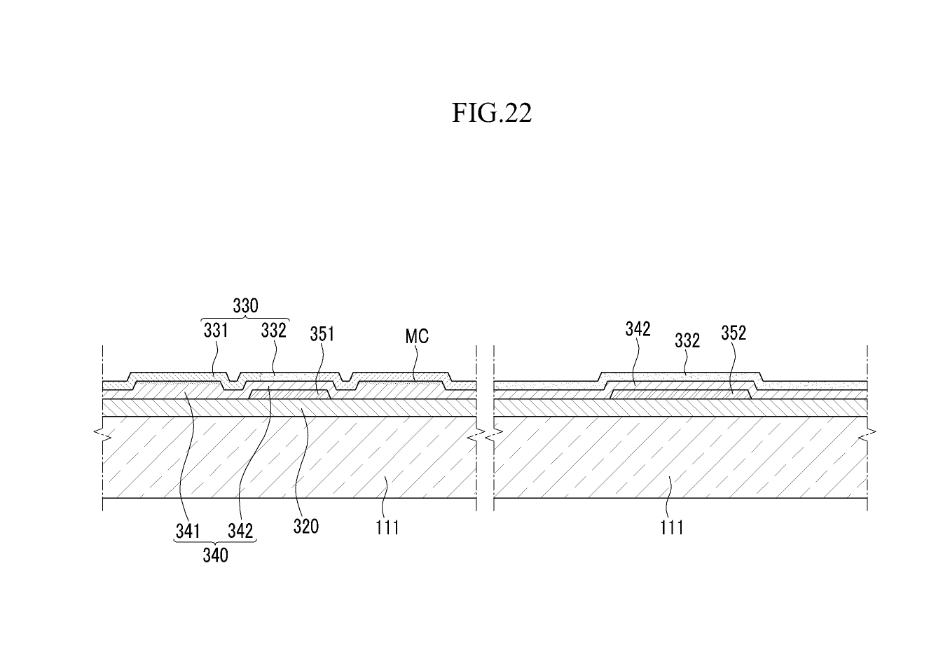

As shown in FIG. 22, an amorphous silicon layer is formed on the insulation layer pattern 340, and is crystallized to form the polycrystalline semiconductor layer 330.

The polycrystalline semiconductor layer 330 is divided into a first crystal area 331 corresponding to the first thickness layer 341 of the insulation layer pattern 340 and a second thickness layer 342 that is near the first thickness layer 341, and a second crystal area 332 corresponding to the other second thickness layer 342 of the insulation layer pattern 340. Here, the first crystal area 331 is crystallized through the metal catalyst (MC), and the second crystal area 332 is solid phase crystallized. In detail, when the amorphous silicon layer that is formed on the insulation layer pattern 340 is heated, the metal catalyst (MC) that is scattered on the first thickness layer 341 of the insulation layer pattern 340 works to grow crystal. The other amorphous silicon layer that is separated from the first thickness layer 341 of the insulation layer pattern 340 by more than a predetermined gap and is not influenced by the metal catalyst (MC) is solid phase crystallized by heat.

In this instance, at least part of the first gate electrode 351 can be overlapped on the second crystal area 332 of the polycrystalline semiconductor layer 330.

As shown in FIG. 17, the source electrodes 171 and 172 and the drain electrodes 173 and 174 are formed to form the first thin film transistor 10 and the second thin film transistor 20.

Through the above-noted manufacturing method, the organic light emitting diode (OLED) display 103 can be manufactured. That is, the first thin film transistor 10 and the second thin film transistor 20 having different characteristics can be simultaneously efficiently formed in the single pixel area.

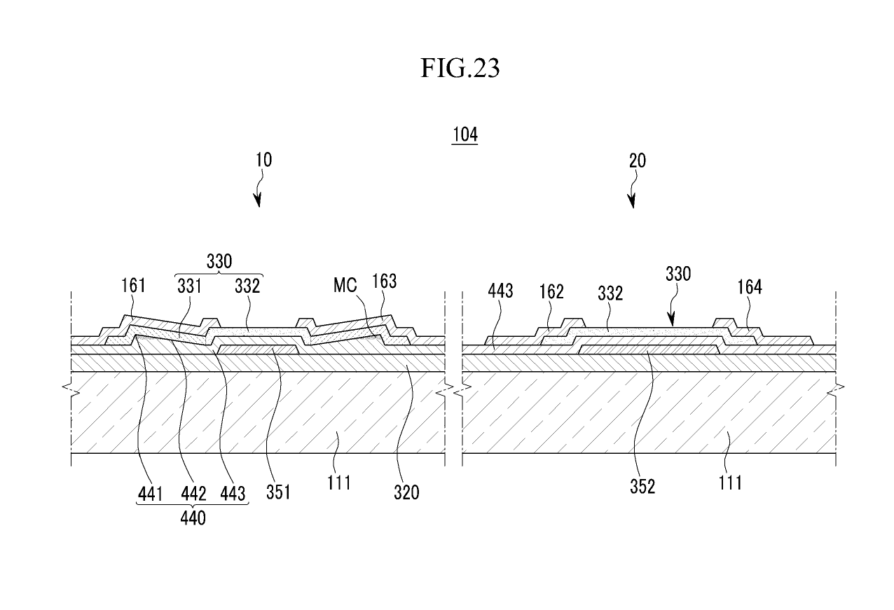

Referring to FIG. 23, an organic light emitting diode (OLED) display 104 according to another embodiment will now be described.

As shown in FIG. 23, the organic light emitting diode (OLED) display 104 is similar to the OLED display 103 of FIG. 17, except that an insulation layer pattern 440 includes a first thickness layer 441, a gradient thickness layer 442, and a second thickness layer 443.

The first thickness layer 441 is relatively the thickest part, and the second thickness layer 443 is relatively the thinnest part. The thickness of the gradient thickness layer 442 is gradually decreased from the first thickness layer 441 to the second thickness layer 443. That is, the gradient thickness layer 442 has a sloped cross-section.

Also, a metal catalyst (MC) such as nickel (Ni) is scattered on a part of the gradient thickness layer 442 and the first thickness layer 441. In this instance, the metal catalyst (MC) is scattered with an amount of dose within the range of 1.0e10 atoms/cm² to 1.0e14 atoms/cm². That is, a small amount of the metal catalyst (MC) is scattered by molecules in the least size on the first thickness layer 441 and a part of the gradient thickness layer 442 of the insulation layer pattern 440. As the thickness of the gradient thickness layer 442 becomes thinner, concentration of the metal catalyst (MC) that is scattered on the surface layer is gradually reduced, and when the thickness thereof becomes less than a predetermined thickness approaching the second thickness layer 443, the metal catalyst (MC) does not substantially exist on the surface layer.

The polycrystalline semiconductor layer 330 formed on the insulation layer pattern 440 is divided into a first crystal area 331 and a second crystal area 332. The first crystal area 331 corresponds to the first thickness layer 441, the gradient thickness layer 442, and a portion of the second thickness layer 443 of the insulation layer pattern 440. The first crystal area 331 is crystallized through the metal catalyst (MC) that is scattered on the first thickness layer 441 and the gradient thickness layer 442 of the insulation layer pattern 440. Additionally, the second crystal area 332 corresponds to the remainder of the second thickness layer 442 of the insulation layer pattern 440. The second crystal area 332 is solid phase crystallized.

Also, growth of the first crystal area 331 is controlled by the gradient thickness layer 442 of the insulation layer pattern 440. In detail, for a gentle gradient of the gradient thickness layer 442, growth of the first crystal area 331 is relatively reduced, and for a steep gradient of the gradient thickness layer 442, growth of the first crystal area 331 is relatively expanded. Therefore, when it is needed to suppress extension of the first crystal area 331 of the polycrystalline semiconductor layer 330 in a predetermined direction with reference to the first thickness layer 441 of the insulation layer pattern 440, the gradient thickness layer 442 need to be formed in the same direction with a gentle gradient.

Accordingly growth of the first crystal area 331 of the polycrystalline semiconductor layer 330 can be efficiently and precisely controlled in the single pixel area (PE) (shown in FIG. 2) and a relatively narrow area.

Through the above-noted configuration, the organic light emitting diode (OLED) display 104 can form the polycrystalline semiconductor layer 330 with a plurality of crystal areas 331 and 332 that are crystallized by different methods in the single pixel area (PE) (shown in FIG. 2) according to usage, and can form a plurality of thin film transistors 10 and 20 with different characteristics in the single pixel area (PE) by using the polycrystalline semiconductor layer 330.

Also, since the growth of the first crystal area 131 can be precisely controlled, the respective parts of the polycrystalline semiconductor layer 330 used for one thin film transistor 10 can be effectively easily crystallized by using different methods.

The source electrodes 161 and 162 and the drain electrodes 163 and 164 connected to a part of the polycrystalline semiconductor layer 330 are formed on the polycrystalline semiconductor layer 330. The source electrodes 161 and 162 and the drain electrodes 163 and 164 are separately disposed.

Furthermore, since the source electrode 161 and the drain electrode 163 are formed on the first thickness layer 441, the gradient thickness layer 442 and a portion of the second thickness layer 443, the source electrode 161 and the drain electrode 163 have the same gradient as the first thickness layer 441, the gradient thickness layer 442 and a portion of the second thickness layer 443.

The first source electrode 161 and the first drain electrode 163 are part of the first thin film transistor 10, and the second source electrode 162 and the second drain electrode 164 are part of the second thin film transistor 20.

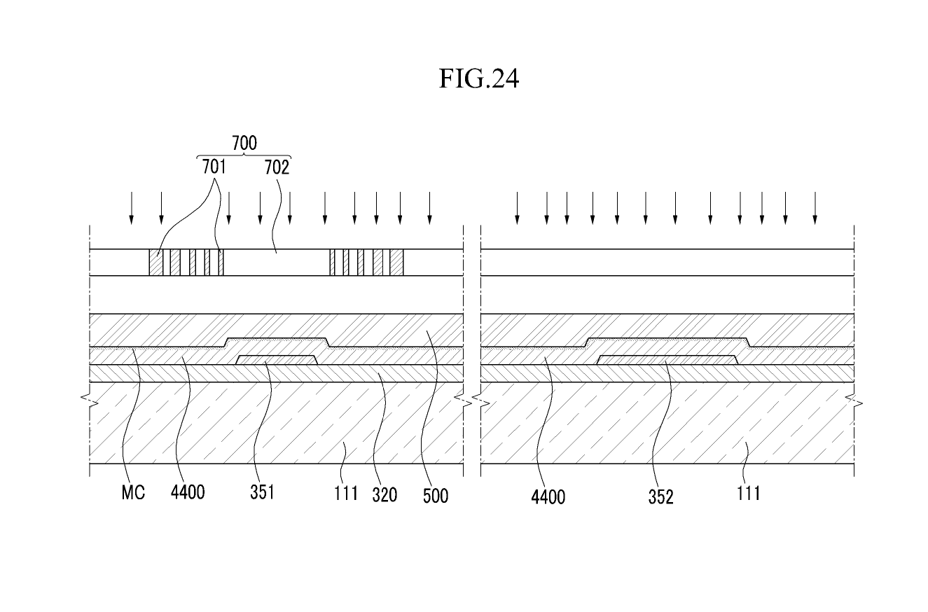

Referring to FIG. 24 to FIG. 27, a method for manufacturing an organic light emitting diode (OLED) display 104 according to the embodiment illustrated in FIG. 23 will now be described.

First, as shown in FIG. 24, a buffer layer 320, first and the second gate electrodes 351 and 352, and an insulation layer 4400 are sequentially formed on the substrate main body 111, and the metal catalyst (MC) such as nickel (Ni) is scattered on the insulation layer 4400.

Next, the photoresist organic film 500 is coated on the insulation layer 4400 on which the metal catalyst (MC) is scattered, and the exposure process is performed by using the mask 600. Here, the mask 700 includes a light shielder 701 and a light transmitter 702. Further, the light shielder 701 of the mask 700 includes a part for gradually controlling exposure. For example, the mask 700 can have a slit pattern of which a gap is gradually variable.

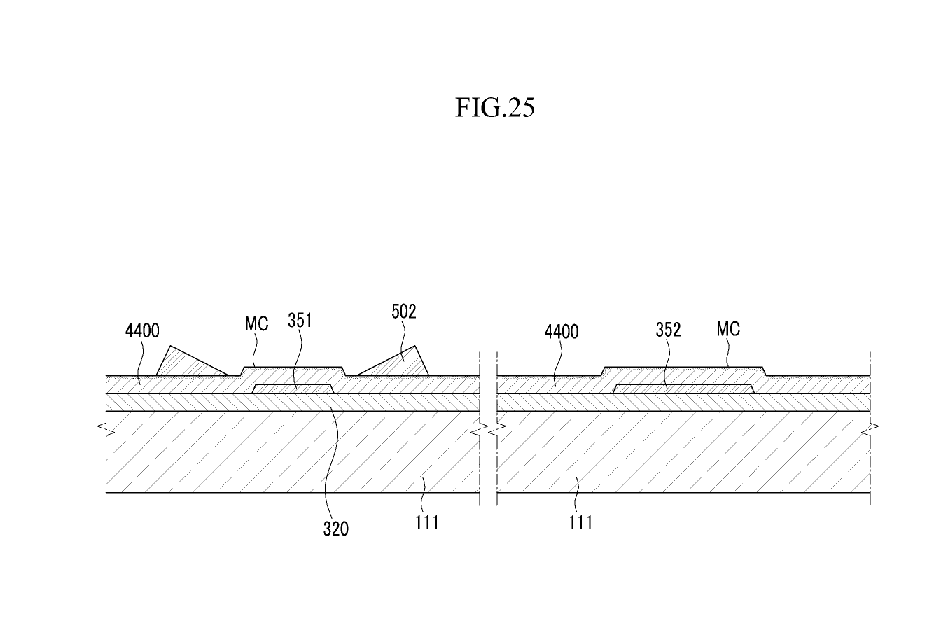

Next, as shown in FIG. 25 the exposed photoresist organic film 500 is formed to form the photoresist pattern 502. In this instance, the photoresist pattern 502 is formed in the gradient structure.

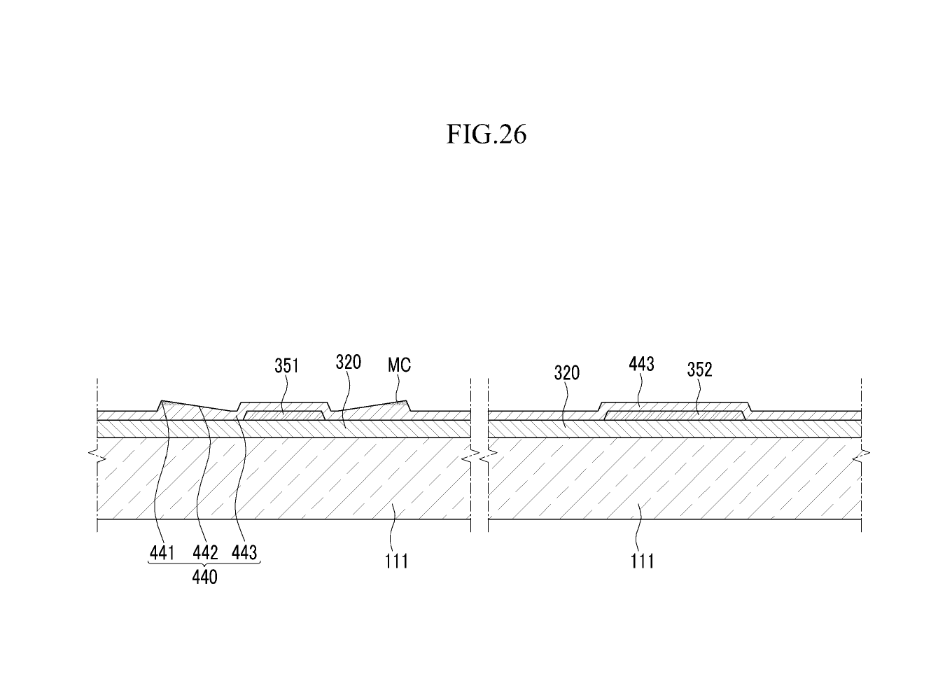

When the insulation layer 4400 on which the metal catalyst (MC) is scattered is partially etched by using the gradient-structured photoresist pattern 502 and the remaining photoresist pattern 502 is removed, the insulation layer pattern 440 shown in FIG. 26 is formed. In detail, the insulation layer pattern 440 includes the first thickness layer 441 that is relatively the thickest, the second thickness layer 443 that is relatively the thinnest, and the gradient thickness layer 442 with a thickness that is gradually decreased from the thickness of the first thickness layer 441 to that of the second thickness layer 443. In this instance, the first thickness layer 441 of the insulation layer pattern 440 has the surface layer on which the metal catalyst (MC) is scattered, and the second thickness layer 443 of the insulation layer pattern 440 loses the surface layer on which the metal catalyst (MC) is scattered. Also, as the thickness of the gradient thickness layer 442 becomes thinner, concentration of the metal catalyst (MC) that is scattered on the surface layer is reduced, and when the thickness becomes less than a predetermined thickness that is near that of the second thickness layer 443, the metal catalyst (MC) does not substantially exist on the surface layer.

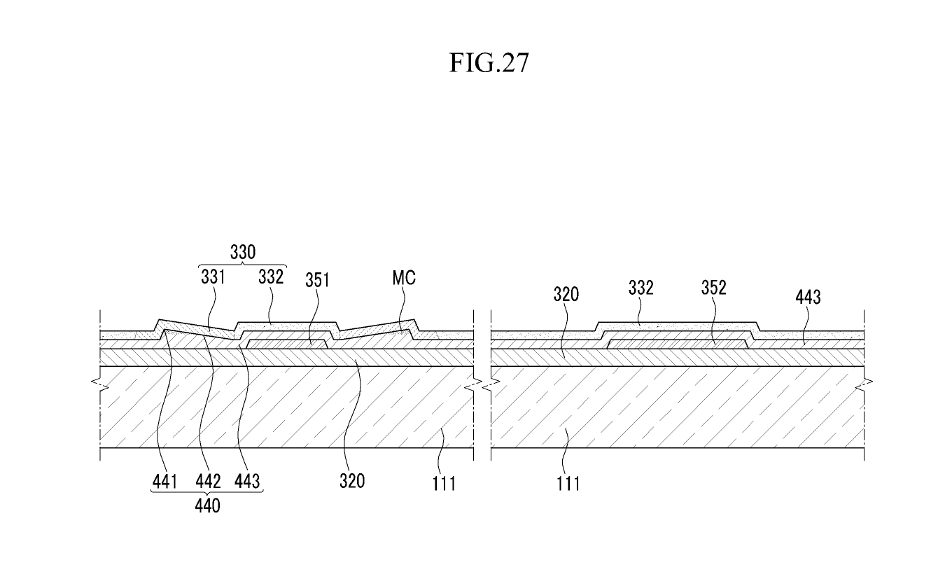

As shown in FIG. 27, when an amorphous silicon layer is formed on the insulation layer pattern 340, it is crystallized to form the polycrystalline semiconductor layer 330.

The polycrystalline semiconductor layer 330 is divided into the first thickness layer 441 and the gradient thickness layer 442 of the insulation layer pattern 440, the first crystal area 331 corresponding to the second thickness layer 443 that is provided near the layers 441 and 442, and the second crystal area 332 corresponding to the remaining second thickness layer 443 of the insulation layer pattern 440. Here, the first crystal area 331 is crystallized through the metal catalyst (MC), and the second crystal area 332 is solid phase crystallized. In detail, when the amorphous silicon layer that is formed on the insulation layer pattern 440 is heated, the metal catalyst (MC) that is scattered on the first thickness layer 441 and the gradient thickness layer 442 of the insulation layer pattern 440 works to perform crystallization. The other amorphous silicon layer that is separated from the first thickness layer 441 of the insulation layer pattern 440 by greater than a predetermined distance and is not influenced by the metal catalyst (MC) is solid phase crystallized by heat.

In this instance, at least a part of the first gate electrode 351 can be overlapped on the second crystal area 332 of the polycrystalline semiconductor layer 330.

As shown in FIG. 23, the first thin film transistor 10 and the second thin film transistor 20 are formed by forming the source electrodes 171 and 172 and the drain electrodes 173 and 174.

Through the above-noted manufacturing method, the organic light emitting diode (OLED) display 104 can be manufactured. That is, the first thin film transistor 10 and the second thin film transistor 20 having different characteristics can be simultaneously efficiently formed in the single pixel area.

Also, since growth of the first crystal area 331 can be precisely controlled through the gradient thickness layer 442 of the insulation layer pattern 440, parts of the polycrystalline semiconductor layer 330 used for the single thin film transistor 10 can be efficiently crystallized by different methods.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A method for manufacturing an organic light emitting diode (OLED) display, comprising:
providing a substrate main body;
forming an insulation layer on the substrate main body;
scattering a metal catalyst on the insulation layer;
forming an insulation layer pattern including a first thickness layer and a second thickness layer that is thinner than the first thickness layer by patterning the insulation layer on which the metal catalyst is scattered through a photolithography process;
forming an amorphous silicon layer on the insulation layer pattern; and
forming a polycrystalline semiconductor layer that is divided into a first crystal area that is crystallized through the metal catalyst by crystallizing the amorphous silicon layer and a second crystal area that is formed through solid phase crystallization (SPC).

2. The method of claim 1, wherein the metal catalyst includes at least one of nickel (Ni), palladium (Pd), titanium (Ti), silver (Ag), gold (Au), tin (Sn), antimony (Sb), copper (Cu), cobalt (Co), molybdenum (Mo), terbium (Tb), ruthenium (Ru), cadmium (Cd), and platinum (Pt).

3. The method of claim 2, wherein a surface layer on which the metal catalyst is scattered is removed from the second thickness layer of the insulation layer pattern.

4. The method of claim 2, wherein the first crystal area of the polycrystalline semiconductor layer corresponds to the first thickness layer of the insulation layer pattern and corresponds to the second thickness layer that is adjacent to the first thickness layer, and the second crystal area of the polycrystalline semiconductor layer corresponds to the remaining second thickness layer of the insulation layer pattern.

5. The method of claim 2, wherein the metal catalyst with a dose amount within the range of 1.0e10 atoms/cm² to 1.0e14 atoms/cm² is scattered on the first thickness layer of the insulation layer pattern.

6. The method of claim 2, wherein the insulation layer pattern includes at least one of tetra ethyl ortho silicate (TEOS), silicon nitride, silicon dioxide, and silicon oxynitride.

7. The method of claim 2, wherein the method further includes:
forming a gate electrode between the substrate main body and the insulation layer pattern to be partially overlapped on the polycrystalline semiconductor layer, and forming a source electrode and a drain electrode on the polycrystalline semiconductor layer to be respectively connected to the polycrystalline semiconductor layer, and
the gate electrode, the polycrystalline semiconductor layer, the source electrode, and the drain electrode form a thin film transistor.

8. The method of claim 7, wherein the thin film transistor includes a first thin film transistor using at least a part of the first crystal area of the polycrystalline semiconductor layer, and a second thin film transistor using the second crystal area of the polycrystalline semiconductor layer.

9. The method of claim 8, wherein the gate electrode is overlapped on the second crystal area of the polycrystalline semiconductor layer.

10. The method of claim 8, wherein the substrate main body includes a plurality of pixel areas, and at least one first thin film transistor and at least one second thin film transistor are respectively formed in the single pixel area.

11. The method of claim 2, wherein the method further includes:
forming a gate electrode separately disposed from the polycrystalline semiconductor layer so as to be partially overlapped on the polycrystalline semiconductor layer, and forming a source electrode and a drain electrode separately disposed from the gate electrode and respectively connected to the polycrystalline semiconductor layer, and
the gate electrode, the polycrystalline semiconductor layer, the source electrode, and the drain electrode form a thin film transistor.

12. The method of claim 11, wherein the thin film transistor includes a first thin film transistor using at least a part of the first crystal area of the polycrystalline semiconductor layer, and a second thin film transistor using the second crystal area of the polycrystalline semiconductor layer.

13. The method of claim 12, wherein the gate electrode is overlapped on the second crystal area of the polycrystalline semiconductor layer.

14. The method of claim 12, wherein the substrate main body includes a plurality of pixel areas, and at least one first thin film transistor and at least one second thin film transistor are respectively formed in the single pixel area.

15. The method of claim 1, wherein the insulation layer pattern further includes a gradient thickness layer having a sloped cross-section extending from the first thickness layer to the second thickness layer.

16. The method of claim 15, wherein the gradient thickness layer of the insulation layer pattern is formed through a gradient-structured photoresist pattern generated by using a mask for gradually controlling exposure.

17. The method of claim 15, wherein when the gradient thickness layer becomes thinner, concentration of the metal catalyst that is scattered on the gradient thickness layer is reduced.

18. The method of claim 17, wherein when the gradient of the gradient thickness layer becomes gentle, the first crystal area of the polycrystalline semiconductor layer is relatively reduced, and when the gradient of the gradient thickness layer becomes sharp, the first crystal area of the polycrystalline semiconductor layer is relatively expanded.

19. The method of claim 15, wherein the first crystal area of the polycrystalline semiconductor layer has a sloped cross-section extending from the first thickness layer to the second thickness layer of the insulation layer pattern.
